(19) United States
(12) Patent Application Publication
(10) Pub. No.: US 2009/0058276 A1
(43) Pub. Date: Mar. 5, 2009

(54) METAL-CONTAINING POLYMERS and uses thereof

(76) Inventor: Bradley J. Holliday, Austin, TX (US)

Correspondence Address: Ballard Spahr Andrews & Ingersoll, LLP, SUITE 1000, 999 PEACHTREE STREET, ATLANTA, GA, 30309-3915, US

(21) Appl. No.: 12/194,815

(22) Filed: Aug. 20, 2008

Related U.S. Application Data
(60) Provisional application No. 60/965,421, filed on Aug. 20, 2007.

(51) Int. Cl. H01J 63/04; C07F 15/00; H01J 9/00

(52) U.S. Cl. 313/504; 546/10; 445/23

(57) ABSTRACT

Disclosed are materials for use in light-emitting devices, devices produced therefrom, and methods for making same. Also disclosed is a light-emitting device comprising: an at least partially electrically conductive oligomer, polymer, or a combination thereof comprising at least one of a lanthanide element, a platinum group metal, or a combination thereof.

### CROSS-REFERENCE TO RELATED APPLICATIONS

This application claims the benefit of U.S. Provisional Application No. 60/965,421 entitled “LANTHANIDE-CONTAINING CONDUCTING POLYMERS AS EMISSIVE MATERIALS” filed Aug. 20, 2007, the entirety of the disclosure of which is expressly incorporated herein by reference.

### BACKGROUND

Light-emitting diodes or devices (LEDs) typically comprise a chip of a semi-conducting material which has been doped or impregnated with impurities to create a p-n junction. In an LED, current flows from the p-side, or anode, of the device to the n-side, or cathode. Charge carriers (electrons and holes) flow into the junction from electrodes with different voltages. When an electron meets a hole, it falls into a lower energy level, and releases energy in the form of a photon.

Recent research has led to the development of organic LEDs (OLEDs) which comprise an organic light-emitting layer. In such devices, the organic light-emitting material can have conjugated π bonds and can thereby function as a semiconductor. The organic light-emitting material can be a small organic molecule in a crystalline phase or a polymer. Some polymeric light-emitting diodes (PLEDs) can be flexible, potentially enabling a more widespread use.

While OLEDs show considerable promise in many applications, the practical implementation of these materials has been hindered by several difficulties. For example, existing materials can have low efficiencies and broad spectral emissions, which can result in poor device performance. Thus, a need exists for new materials and methods that overcome challenges in the art, a few of which are mentioned above. These needs and other needs are at least partially satisfied by the present invention.

### SUMMARY

In accordance with the purpose(s) of the invention, as embodied and broadly described herein, the invention, in one aspect, relates to materials for use in light-emitting devices, devices produced therewith, and methods for making same.

In one aspect, disclosed are light-emitting devices comprising: an electrically conductive oligomer, polymer, or a combination thereof, wherein the electrically conductive oligomer, polymer, or combination thereof comprises at least one of a lanthanide element, a platinum group metal, or a combination thereof.

In a further aspect, disclosed are compounds, and oligomers and/or polymers produced therefrom, methods of making same, and devices comprising same.

In a still further aspect, disclosed are methods for producing a polymeric light-emitting device comprising: providing at least one electrode with at least one monomer positioned thereon; and polymerizing the at least one monomer to provide a polymeric layer; wherein the at least one monomer and polymeric layer produced therefrom comprises at least one of a lanthanide element, a platinum group metal, or a combination thereof, and wherein the polymeric layer is electrically conductive; thereby producing the polymeric light-emitting device.

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

The accompanying figures, which are incorporated in and constitute a part of this specification, illustrate several aspects and together with the description serve to explain the principles of the invention.

### BRIEF DESCRIPTION OF THE FIGURES

FIG. 1 is an illustration of an OLED;

FIG. 2 is a schematic illustration of an OLED made in accordance with the teachings herein;

FIG. 3 is an illustration of the photo physics of lanthanide-containing materials;

FIG. 4 is the adsorption and emission spectra of TP₂BPY and TP₂Phen ligands at room temperature;

FIG. 5 is the emission spectra of Gd[TP₂BPY]₃ and Gd[TP₂Phen]₃ at room temperature and at 77K;

FIG. 6 is the emission spectra of Gd(DBM)₃[TP₂BPY]₃, Gd(DBM)₃[TP₂Phen] and Gd(DBM)₃(H₂O)₂ at room temperature and at 77K;

FIG. 7 is an illustration of a particular, non-limiting embodiment of a class of polymers made in accordance with the teachings herein;

FIG. 8 is an illustration of a particular, non-limiting embodiment of a class of monomers made in accordance with the teachings herein;

FIG. 9 is an illustration of the crystallographic structure of the Yb species of the monomer of FIG. 8;

FIG. 10 is an illustration of the crystallographic structure of the Eu species of the monomer of FIG. 8;

FIG. 11 is an illustration of the coordination polyhedron of the Eu⁺³ ion;

FIG. 12 is the adsorption spectrum of Eu(DBM)₃[(TP)₂BPY];

FIG. 13 is the absorption (200-500 nm), emission spectrum (360-750 nm), and excitation spectrum (200-450 nm) of Eu(DBM)₃[(TP)₂BPY];

FIG. 14 is the emission spectrum of Eu(DBM)₃[(TP)₂BPY] in toluene;

FIG. 15 is the emission spectrum of Eu(DBM)₃[(TP)₂BPY] in the solid state;

FIG. 16 is the emission spectrum of Sm(DBM)₃[(TP)₂BPY] in toluene;

FIG. 17 is the emission spectrum of Sm(DBM)₃[(TP)₂BPY] in the solid state;

FIG. 18 is the emission spectrum of Tb(DBM)₃[(TP)₂BPY] in toluene and in the solid state;

FIG. 19 is an illustration of a suitable synthetic route which can be utilized to synthesize Ln(DBM)₃[(TP)₂Phen];

FIG. 20 is an illustration of a synthetic route suitable for making some of the monomers described herein;

FIG. 21 is an illustration of a particular, non-limiting embodiment of a class of monomers made in accordance with the teachings herein;

FIG. 22 is an illustration of the crystallographic structure of the Eu species of the monomer of FIG. 21;

FIG. 23 is an illustration of the crystallographic structure of the Yb species of the monomer of FIG. 21;

FIG. 24 is an illustration of the coordination polyhedron of the Yb⁺³ ion;

FIG. 25 is the absorption spectrum (300-500 nm), emission spectrum (410-750 nm), and excitation spectrum (325-450) of Eu(DBM)₃[(TP)₂Phen];

FIG. 26 is the adsorption and emission spectrum of Eu(DBM)₃[(TP)₂Phen];

FIG. 27 is the emission spectrum of Eu(DBM)₃[(TP)₂Phen] in DCB;

FIG. 28 is the emission spectrum of Eu(DBM)₃[(TP)₂Phen] in the solid state;

FIG. 29 is the emission spectrum of Sm(DBM)₃[(TP)₂Phen] in DCB;

FIG. 30 is the emission spectrum of Sm(DBM)₃[(TP)₂Phen] in the solid state;

FIG. 31 is the emission spectrum of Tb(DBM)₃[(TP)₂Phen] in toluene and in the solid state;

FIG. 32 is an illustration of the crystallographic structure of the Eu species of the monomer of FIG. 33;

FIG. 33 is an illustration of a formula of an exemplary embodiment;

FIG. 34 is a cyclic voltammogram of the species of FIG. 33;

FIG. 35 is a graph summarizing the results of the cyclic voltammogram of FIG. 34;

FIG. 36 is a graph depicting cyclic voltammogram data for the constituent portions of the monomer of FIG. 33;

FIG. 37 is a graph of cyclic voltammogram data pertaining to the monomer of FIG. 33;

FIG. 38 is a compilation of UV visible spectra showing the UV-visible absorption spectra of ligand (EDOT)₂Phen, Eu(DBM)₃[(EDOT)₂Phen] (▴) and the excitation spectra of Eu(DBM)₃[(EDOT)₂Phen] (-), film (-) and the emission spectra of the complex (broad, 400-525 nm) and film (sharp, 600-625 nm);

FIG. 39 is an illustration of a particular, non-limiting species of a polymer made in accordance with the teachings herein;

FIG. 40 is an illustration of the crystallographic structure of the species of FIG. 39;

FIG. 41 is a cyclic voltammogram of the species of FIG. 39; and

FIG. 42 is a graph summarizing the data from the cyclic voltammogram of FIG. 41.

FIG. 43 is a plot of (A) absorption and emission of exemplary Ru complexes and polymers thereof and (B) photophysical characterization of exemplary Ru-based polymers.

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DETAILED DESCRIPTION

Before the present compounds, compositions, articles, systems, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

All publications mentioned herein are incorporated by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates.

A. Definitions

As used in the specification and the appended claims, the singular forms “a,” “an” and “the” include plural referents unless the context clearly dictates otherwise. Thus, for example, reference to “an electrode,” “a polymer,” or “a material” includes mixtures of two or more such electrodes, polymers, or materials, and the like.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “optional” or “optionally” means that the subsequently described event or circumstance can or can not occur, and that the description includes instances where said event or circumstance occurs and instances where it does not.

Disclosed are the components to be used to prepare the compositions of the invention as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds can not be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

It is understood that the compositions disclosed herein have certain functions. Disclosed herein are certain structural requirements for performing the disclosed functions, and it is understood that there are a variety of structures that can perform the same function that are related to the disclosed structures, and that these structures will typically achieve the same result.

A residue of a chemical species, as used in the specification and concluding claims, refers to the moiety that is the resulting product of the chemical species in a particular reaction scheme or subsequent formulation or chemical product, regardless of whether the moiety is actually obtained from the chemical species. Thus, a thiopene residue in a polythiophene refers to one or more thiophene units in the polythiophene, regardless of whether thiophene was used to prepare the polythiophene.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. The term “optionally substituted,” means that the compound, atom, or residue can or cannot be substituted, as defined herein.

In defining various terms, “A¹,” “A²,” “A³,” and “A⁴” are used herein as generic symbols to represent various specific substituents. These symbols can be any substituent, not limited to those disclosed herein, and when they are defined to be certain substituents in one instance, they can, in another instance, be defined as some other substituents.

The term “alkyl” as used herein is a branched or unbranched saturated hydrocarbon group of 1 to 24 carbon atoms, 1 to 20 carbons, 1 to 18 carbons, 1 to 16 carbons, 1 to 14 carbons, 1 to 10 carbons, 1 to 8 carbons, 1 to 6 carbons, 1 to 4 carbons, 1 to 3 carbons, or 1 to 2 carbons, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dode cyl, tetradecyl, hexadecyl, eicosyl, tetracosyl, and the like. The alkyl group can also be substituted or unsubstituted. The alkyl group can be substituted with one or more groups including, but not limited to, optionally substituted alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbomyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, optionally substituted alkyl, cycloalkyl, alkoxy, amino, ether, halide, hydroxy, nitro, silyl, sulfo-oxo, or thiol as described herein.

The terms “alkoxy” and “alkoxyl” as used herein to refer to an alkyl or cycloalkyl group bonded through an ether linkage; that is, an “alkoxy” group can be defined as —OA¹ where A¹ is alkyl or cycloalkyl as defined above. “Alkoxy” also includes polymers of alkoxy groups as just described; that is, an alkoxy can be a polyether such as -OA¹-OA² or -OA¹-(OA²)ₐ-OA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, optionally substituted alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, optionally substituted alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, optionally substituted alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, optionally substituted alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, optionally substituted alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “organic residue” defines a carbon containing residue, i.e., a residue comprising at least one carbon atom, and includes but is not limited to the carbon-containing groups, residues, or radicals defined hereinabove. Organic residues can contain various heteroatoms, or be bonded to another molecule through a heteroatom, including oxygen, nitrogen, sulfur, phosphorus, or the like. Examples of organic residues include but are not limited alkyl or substituted alkyls, alkoxy or substituted alkoxy, mono or di-substituted amino, amide groups, etc. Organic residues can preferably comprise 1 to 18 carbon atoms, 1 to 15, carbon atoms, 1 to 12 carbon atoms, 1 to 8 carbon atoms, 1 to 6 carbon atoms, or 1 to 4 carbon atoms. In a further aspect, an organic residue can comprise 2 to 18 carbon atoms, 2 to 15, carbon atoms, 2 to 12 carbon atoms, 2 to 8 carbon atoms, 2 to 4 carbon atoms, or 2 to 4 carbon atoms

A very close synonym of the term “residue” is the term “radical,” which as used in the specification and concluding claims, refers to a fragment, group, or substructure of a molecule described herein, regardless of how the molecule is prepared. For example, a 2,4-thiazolidinedione radical in a particular compound can have the structure

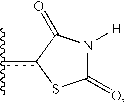

regardless of whether thiazolidinedione is used to prepare the compound. In some embodiments the radical (for example an alkyl) can be further modified (i.e., substituted alkyl) by having bonded thereto one or more “substituent radicals.” The number of atoms in a given radical is not critical to the present invention unless it is indicated to the contrary elsewhere herein.

“Organic radicals,” as the term is defined and used herein, contain one or more carbon atoms. An organic radical can have, for example, 1-26 carbon atoms, 1-18 carbon atoms, 1-12 carbon atoms, 1-8 carbon atoms, 1-6 carbon atoms, or 1-4 carbon atoms. In a further aspect, an organic radical can have 2-26 carbon atoms, 2-18 carbon atoms, 2-12 carbon atoms, 2-8 carbon atoms, 2-6 carbon atoms, or 2-4 carbon atoms. Organic radicals often have hydrogen bound to one or more of the carbon atoms of the organic radical. One example of an organic radical that comprises no inorganic atoms is a 5, 6, 7, 8-tetrahydro-2-naphthyl radical. In some embodiments, an organic radical can contain 1-10 inorganic heteroatoms bound thereto or therein, including halogens, oxygen, sulfur, nitrogen, phosphorus, and the like. Examples of organic radicals include but are not limited to an alkyl, substituted alkyl, cycloalkyl, substituted cycloalkyl, mono-substituted amino, di-substituted amino, acyloxy, cyano, carboxy, carboalkoxy, alkylcarboxamide, substituted alkylcarboxamide, dialkylcarboxamide, substituted dialkylcarboxamide, alkylsulfonyl, alkylsulfinyl, thioalkyl, thiohaloalkyl, alkoxy, substituted alkoxy, haloalkyl, haloalkoxy, aryl, substituted aryl, heteroaryl, heterocyclic, or substituted heterocyclic radicals, wherein the terms are defined elsewhere herein. A few non-limiting examples of organic radicals that include heteroatoms include alkoxy radicals, trifluoromethoxy radicals, acetoxy radicals, dimethylamino radicals and the like.

“Inorganic radicals,” as the term is defined and used herein, contain no carbon atoms and therefore comprise only atoms other than carbon. Inorganic radicals comprise bonded combinations of atoms selected from hydrogen, nitrogen, oxygen, silicon, phosphorus, sulfur, selenium, and halogens such as fluorine, chlorine, bromine, and iodine, which can be present individually or bonded together in their chemically stable combinations. Inorganic radicals can, in one aspect, have 10 or fewer, or in a further aspect, one to six or one to four inorganic atoms as listed above bonded together. Examples of inorganic radicals include, but not limited to, amino, hydroxy, halogens, nitro, thiol, sulfate, phosphate, and like commonly known inorganic radicals. The inorganic radicals do not have bonded therein the metallic elements of the periodic table (such as the alkali metals, alkaline earth metals, transition metals, lanthanide elements, or actinide metals), although such metal ions can sometimes serve as a cation for anionic inorganic radicals such as a sulfate, phosphate, or like anionic inorganic radical. Inorganic radicals do not comprise metalloids elements such as boron, aluminum, gallium, germanium, arsenic, tin, lead, or tellurium, or the noble gas elements, unless otherwise specifically indicated elsewhere herein.

Compounds described herein can contain one or more double bonds and, thus, potentially give rise to cis/trans (E/Z) isomers, as well as other conformational isomers. Unless stated to the contrary, the invention includes all such possible isomers, as well as mixtures of such isomers.

If a disclosed chemical species is said to be “conjugated,” it is meant that the chemical species has at least two conjugated π bonds. For example, if a chemical species has alternating π and sigma bonds, that chemical species is conjugated. In one aspect, conjugation refers to at least partial electron (e.g., π electron) delocalization, although conjugation does not guarantee electron delocalization. An example of a conjugated chemical species is an aryl group, as discussed herein.

Unless stated to the contrary, a formula with chemical bonds shown only as solid lines and not as wedges or dashed lines contemplates each possible isomer, e.g., each enantiomer and diastereomer, and a mixture of isomers, such as a racemic or scalemic mixture. Compounds described herein can contain one or more asymmetric centers and, thus, potentially give rise to diastereomers and optical isomers. Unless stated to the contrary, the present invention includes all such possible diastereomers as well as their racemic mixtures, their substantially pure resolved enantiomers, all possible geometric isomers, and pharmaceutically acceptable salts thereof. Mixtures of stereoisomers, as well as isolated specific stereoisomers, are also included. During the course of the synthetic procedures used to prepare such compounds, or in using racemization or epimerization procedures known to those skilled in the art, the products of such procedures can be a mixture of stereoisomers.

B. Light-Emitting Device

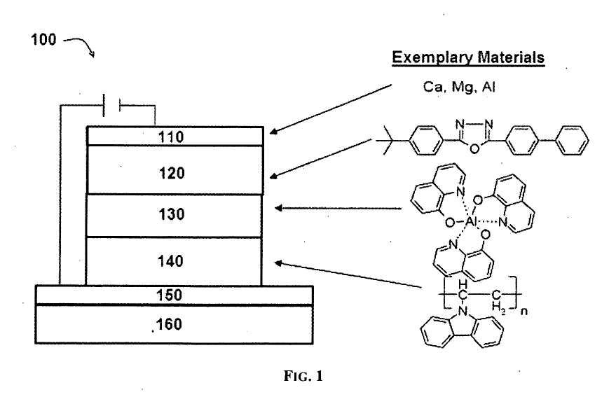

With reference to FIG. 1, a conventional OLED device (100) typically comprises a cathode (110) (typically a high work function metal), an electron transport layer (120), an emission layer (130), a hole transport layer (140), an anode (150), and a transparent substrate (160), such as glass or plastic. Some exemplary materials utilized in each of these layers are also indicated in FIG. 1. In one aspect, an OLED can be flexible, which allows it to be formed on a variety of substrates. Devices of this type can be fabricated, for example, through clean room vapor deposition techniques.

During OLED use, current can be passed between the anode and the cathode, thereby inducing the generation of holes and electrons. The charge carriers can then diffuse toward each other and meet at the emission layer, exciting the emitting compound, thereby resulting in luminescence.

In one aspect, a disclosed anode can comprise a conducting oxide, such as, for example, tin oxide, indium-tin oxide (ITO). Further examples of anode materials useful with a disclosed embodiment are other metal oxides including, but not limited to, aluminum- or indium-doped zinc oxide, magnesium-indium oxide, and nickel-tungsten oxide. In addition to these oxides, metal nitrides such as gallium nitride, metal selenides such as zinc selenide, and metal sulfides such as zinc sulfide, can be used as an anode material.

Desirable cathodes can, in one aspect, have good film-forming properties to ensure good contact with the underlying organic or polymer layer, and be able to at least partially promote electron injection at low voltage. Useful cathode materials often contain a low work function metal (<4.0 eV) or metal alloy. In one aspect, a thin metal layer can be used as the outer layer to form a semi-transparent cathode. Suitable metals include gold, silver, aluminum, nickel, palladium, and platinum, tin (e.g., ITO), and the like.

In one aspect, a disclosed light-emitting device comprises an electrically conductive oligomer, polymer, or a combination thereof, wherein the electrically conductive oligomer, polymer, or combination thereof comprises at least one of a lanthanide element, a platinum group metal, or a combination thereof. In one specific aspect, the light-emitting device comprises a lanthanide element. In another specific aspect, the light-emitting device comprises a platinum group metal, such as, for example, platinum, ruthenium, iridium, or a combination thereof. In a further aspect, the at least one lanthanide element can be present in a complex that is bonded, for example, to the oligomer, polymer, or combination thereof through at least one covalent, electrostatic, ionic, or dative bond. In a still further aspect, the at least one lanthanide element can be present in a complex that is covalently bonded to, for example, the electrically conductive oligomer, polymer, or combination thereof. In an exemplary material, the electrically conductive oligomer, polymer, or combination thereof comprises at least two conjugated π bonds.

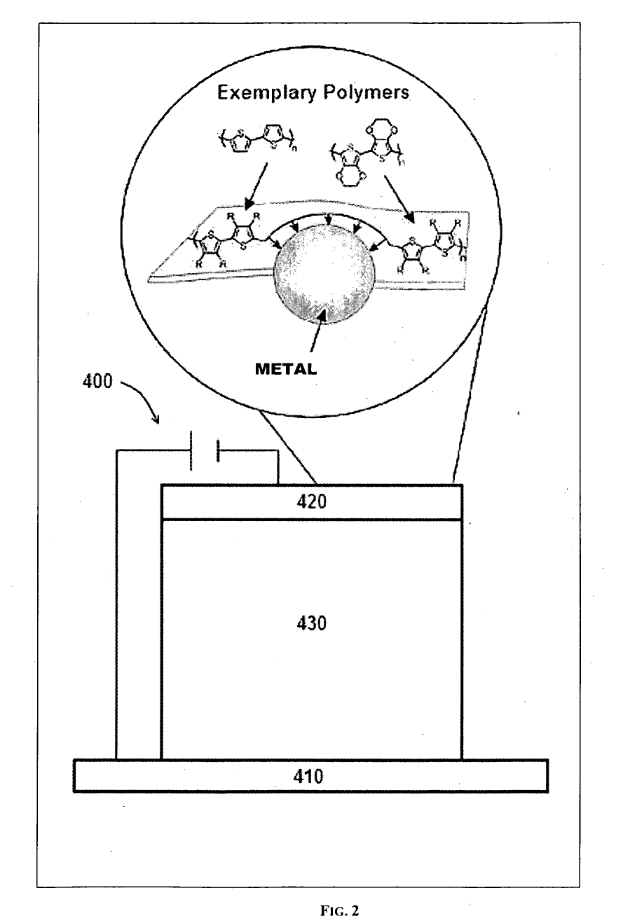

In a further aspect, a disclosed device (400) comprises an anode (410), a cathode (420), and a light-emitting layer (430) positioned therebetween, wherein the light-emitting layer comprises the electrically conductive oligomer, polymer, or combination thereof. For example, with reference to FIG. 2, an exemplary can comprise a substrate, an anode, an emission layer, and a cathode. The emission layer in the device of FIG. 2 can be a single layer structure or a multilayer structure. A single layer structure can be formed by methods known in the art, such as, for example, by electrochemical deposition. Thus, in one aspect, OLEDs made with a disclosed material can be fabricated in solution, and thus need not require the use of clean room techniques.

In one aspect, the electrically conductive oligomer, polymer, or combination thereof can function as a light emissive material, a hole transport material, and/or an electron transport material. For example, a single layer structure comprising a disclosed material can perform the function of a multilayered structure in an OLED (i.e., a single material which is a hole transporter, an electron transporter, and which is also a light emitter). In one aspect, the device does not comprise a distinct electron transport and hole transport layer.

In a further aspect, the device can comprise a layered structure positioned at least partially on a substrate; wherein the layered structure comprises, or in the alternative, consists essentially of, an anode, a cathode, and a light-emitting layer positioned therebetween, wherein the light-emitting layer comprises the electrically conductive monomer, oligomer, polymer, or combination thereof.

While the disclosed materials are suitable for use in a single layer structure device, it should also be appreciated that the disclosed materials can be used in combination with a multilayered device structure, such as that depicted in FIG. 1.

In a further aspect, a disclosed material can comprise an electrically conducting polymer which can provide the requisite charge carrier transfer properties, and which can also at least partially also bind at least one of a lanthanide element, a platinum group metal, or a combination thereof. Such a polymer can provide, for example, a more intimate and more efficient communication between the lanthanide and the polymer. Consequently, when electricity is injected into the material, excited states can be generated, and in various aspects, the energy from the excited states can be transferred to the lanthanide, thereby inducing light emission. Thus, in one aspect, a disclosed material can provide improved efficiency by minimizing the generation of heat and the generation of excited states that do not result in light emission.

In a still further aspect, the incorporation of a lanthanide element into the disclosed material can render the material capable of harvesting both singlet and triplet excitons generated in a light-emitting device, which, in one aspect, can increase the overall efficiency of the device incorporating these materials. A further advantage is that these materials can display sharp, lanthanide-based light emission due to the inner-shell electronic transition from which it emanates. This sharp emission can lead to pure color in devices that utilize these materials.

In one aspect, the at least one lanthanide element can be in electronic communication with the oligomer or polymer backbone. As used herein, the term “electronic communication,” is meant to refer to at least partial electron delocalization (whether induced upon excitation or present at a ground state). For example, if a lanthanide element is bound to an oligomer or polymer, the lanthanide element and oligomer or polymer would be said to be in electronic communication if charge transfer or electron delocalization could occur. It will be appreciated that by engineering a material in this manner, in accordance with the present disclosure, that the need for a multilayered structure can be obviated. That is, the emitting center can be directly interfaced with the conducting oligomer or polymer, thus improving the communication between the two materials. Consequently, energy transfer from the active host conducting polymer matrix to the lanthanide element can be enhanced, and single layer devices can be attainable.

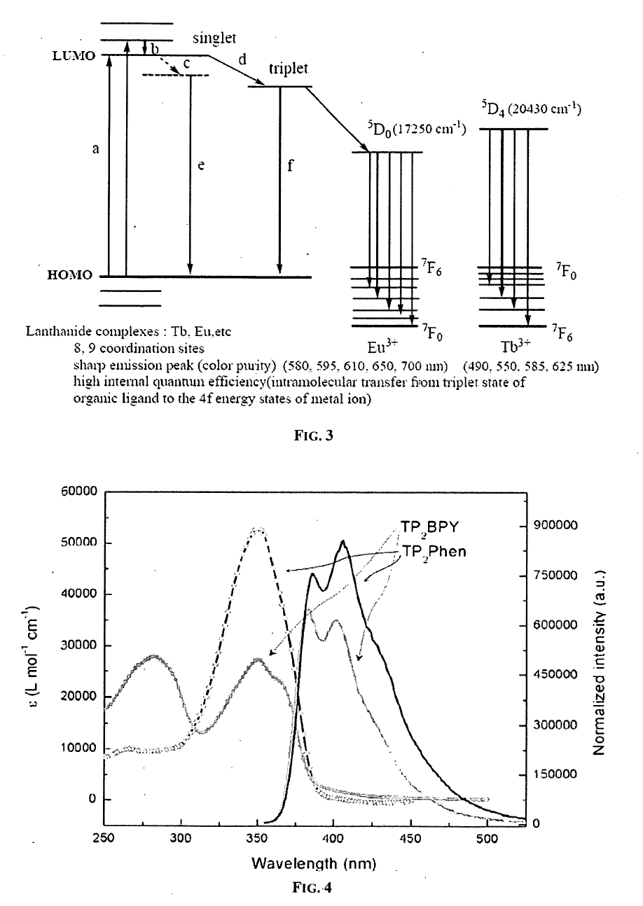

With reference to FIG. 3, an exemplary photon induced cascade of energy through a disclosed lanthanide complex can be achieved upon excitation. As shown in FIG. 3, the process can begin with UV visible absorption, as indicated by arrow “a,” which results in a singlet excited state. Inter system crossing can then occur as indicated by arrow “d,” thereby resulting in a triplet excited state. Energy transfer to the lanthanide can then occur, as indicated by the arrow. The lanthanide can then cascade down to the ground state, giving off light in the process. It will be appreciated from the foregoing discussion that both photoluminescence and electrical luminescence inherently involve the same excited states. Thus, in one aspect, the disclosed materials can be useful in applications involving photoluminescence as well as an electrical luminescence.

In a further aspect, a disclosed electrically conductive polymer can provide a means to tailor the properties of a device or a material therein. For example, the conducting polymer portion of a disclosed material can be modified to change the excited state and thereby change the conductivity properties of the material. Also, for example, the lanthanide element can also be changed, which can change the wavelength of the light that is emitted. It should be appreciated that through the appropriate choice of a lanthanide, it can be possible to tune the wavelength or color emission of the material, for example, to emit red, green, and/or blue light.

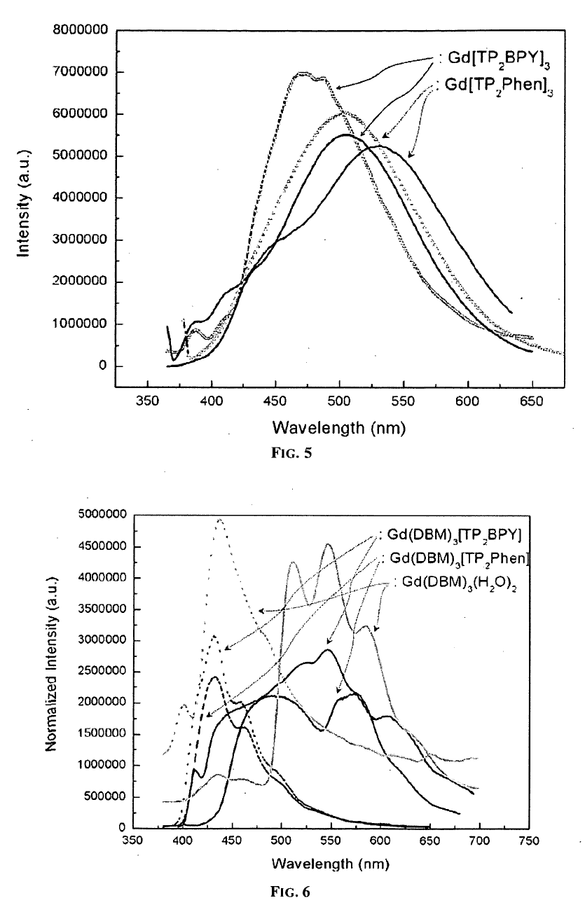

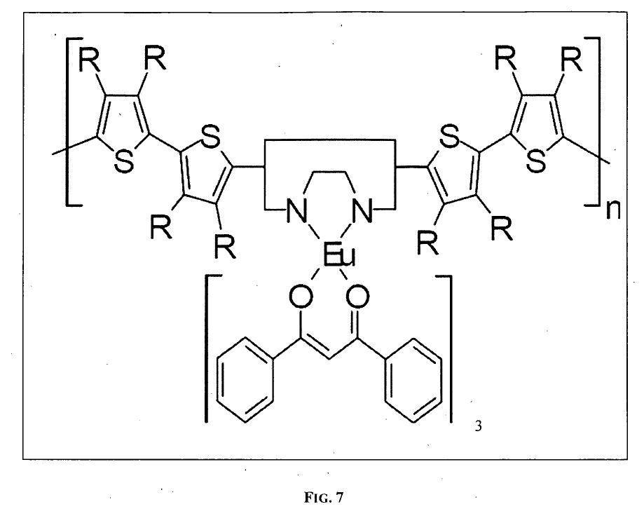

FIGS. 4-6 show results of the characterization of the excited state of an exemplary disclosed polymer that can provide guidance in tuning such materials. For example, tuning can comprise incorporating Gd into the film, and then observing the resultant photo physics and comparing the results to those achieved with another lanthanide. The use of Gd, for example, can determine where the energy level of the triplet state of the ligand will lie.

In a further aspect, through the choice of a lanthanide, a disclosed material can be made to emit narrow band electromagnetic radiation in the near infrared region of the spectrum, thus making the material useful for applications which desire narrow band infrared sources. Such applications include, for example, medical imaging, infrared tagging applications, and military applications (including, for example, applications in targeting systems and friend or foe detection).

C. Structure and Properties of Disclosed Materials

The disclosed materials generally comprise at least one of a lanthanide element, a platinum group metal, or a combination thereof, and one or more ligands bonded (e.g., covalent, dative, ionic, electrostatic, and the like) thereto, wherein one or more of the ligands are also bound to an at least partially conducting polymer. In one aspect, a disclosed material has a structure represented by a formula:

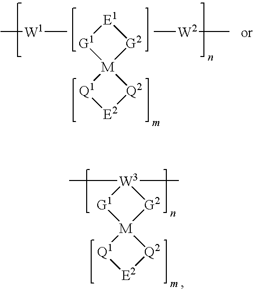

wherein m, and n≧1; wherein M is a lanthanide element or a platinum group metal; wherein W¹, W² and W³ are conjugated radicals and are the same or different; wherein G¹ and G² are, independently, electron donors; wherein Q¹ and Q² are, independently, electron donors; and wherein E¹ and E² are an organic residue of a ligand.

In one aspect, M comprises a lanthanide element, such as, for example, Sm, Eu, Gd, Tb, Dy, Yb, Er, Nd, or a combination thereof. In a further aspect, M has an atomic number from 58 to 71. In another aspect, M comprises a platinum group metal, such as, for example, platinum, ruthenium, iridium, or a combination thereof

In a further aspect, the moiety:

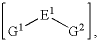

has a structure represented by a general formula:

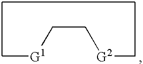

wherein G¹ and G² are nitrogen. Thus, in this example, nitrogen is the electron donor. Other examples of electron donors include heteroaryl compounds having a structure represented by a formula:

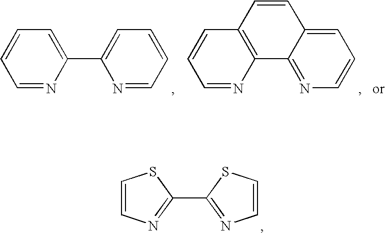

or a combination thereof.

While the examples provided include neutral electron donors, ligands suitable for use with the disclosed materials are not limited to such. For example, an anionic electron donor can be used.

In a further aspect, a disclosed compound can comprise a platinum group element, such as, for example, Ir, Pt, Ru, or a combination thereof.

In one aspect, the moiety having the general formula:

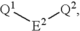

can have a structure represented by a formula:

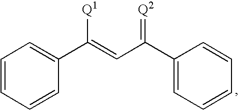

wherein Q¹ and Q² are oxygen. Although no ring substituents are shown in this structure, it is contemplated that any substituent can be present, such as for example, an electron donating or withdrawing group. Examples of electron donating groups include alkyl groups and hydroxyl groups, as defined herein. Examples of electron withdrawing groups include carbonyl groups, such as, for example, a ketone.

In one aspect, W¹ has a structure represented by a formula:

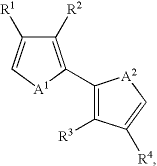

wherein R¹, R², R³ and R⁴ are independently selected from the group consisting of hydrogen, alkyl, and aryl radicals, wherein the alkyl and aryl radicals can be substituted with one or more hetero atoms and/or one or more halogen atoms, and with the proviso that any two or more of R¹, R², R³ and R⁴ can combine to form a polyvalent radical; and wherein A¹ and A² are independently a heteroatom, such as, for example, O or S.

In one aspect, W² has a structure represented by a formula:

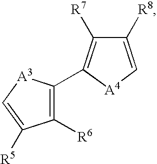

wherein R⁵, R⁶, R⁷ and R⁸ are independently selected from the group consisting of hydrogen, alkyl, and aryl radicals, wherein the alkyl and aryl radicals can be substituted with one or more hetero atoms and/or one or more halogen atoms, and with the proviso that any two or more of R⁵, R⁶, R⁷ and R⁸ can combine to form a polyvalent radical; and wherein A³ and A⁴ are independently a heteroatom, such as, for example, O or S.

In one aspect, the residue represented by the formula:

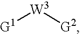

can be present as:

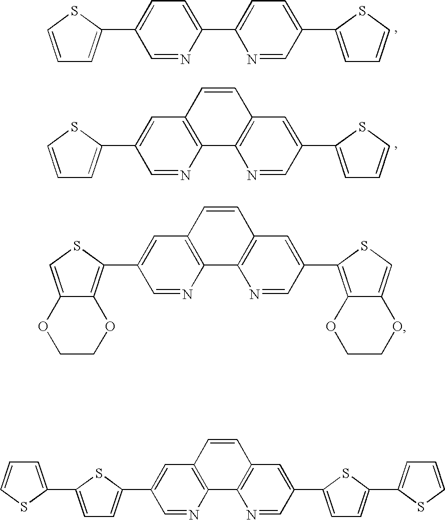

In one aspect, a disclosed material has a structure represented by a formula:

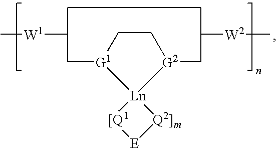

wherein m, n≧1; wherein Ln is an element selected from the Lanthanide series; wherein W¹ and W² are conjugated radicals and are the same or different; wherein G¹ and G² are independently selected from the group consisting of divalent radicals; wherein Q¹ and Q² are independently selected from the group consisting of divalent radicals; and wherein E¹ and E² are independently selected from the group consisting of divalent radicals. In one aspect, E is a conjugated divalent linking group.

In a further aspect, a disclosed material has a structure represented by a formula:

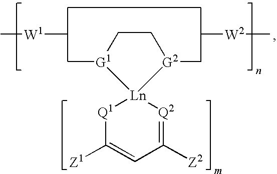

wherein m, n≧1; wherein Ln is an element selected from the Lanthanide series; wherein W¹ and W² are conjugated radicals and are the same or different; wherein Z¹ and Z² are conjugated radicals and are the same or different; wherein G¹ and G² are independently selected from the group consisting of trivalent radicals; and wherein Q¹ and Q² are independently selected from the group consisting of divalent and trivalent radicals.

In one aspect, the electrically conductive oligomer, polymer, or combination thereof has a structure represented by a formula:

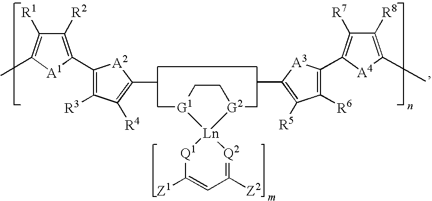

wherein m, n≧1; wherein Ln is an element selected from the Lanthanide series; wherein R¹, R², R³, R⁴, R⁵and R⁶ are independently selected from the group consisting of hydrogen, alkyl, and aryl radicals, wherein the alkyl and aryl radicals can be substituted with one or more hetero atoms and/or one or more halogen atoms, and with the proviso that any two or more of R¹, R², R³, R⁴, R⁵ and R⁶ can combine to form a polyvalent radical; wherein A¹, A², A³, and A⁴ are independently selected from the group consisting of divalent radicals; wherein G¹ and G² are independently selected from the group consisting of trivalent radicals; and wherein Q¹ and Q² are independently selected from the group consisting of divalent radicals.

In one aspect, the electrically conductive oligomer, polymer, or combination thereof has a structure represented by a formula:

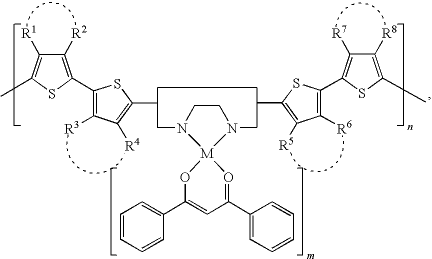

wherein m is an integer from 1 to 3; wherein n≧1; wherein M is a lanthanide element is present as lanthanum, cerium, praseodymium, neodymium, promethium, samarium, europium, gadolinium, terbium, dysprosium, holmium, erbium, thulium, ytterbium, lutetium; wherein R¹, R², R³, R⁴, R⁵, R⁶, R⁷, and R⁸ are hydrogen, or an optionally substituted organic residue comprising from 1 to 8 carbons; wherein [symbol] is an optional bond; and wherein

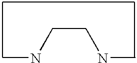

is present as an optionally substituted aryl or optionally substituted heteroaryl residue.

The integer n in a disclosed material refers to the degree of polymerization of a disclosed polymer. In one aspect, when a disclosed polymer is formed on a substrate, the degree of polymerization can be difficult to determine. However, in light the resulting properties of a disclosed polymer film, it is apparent that n is greater than or equal to 1. In one aspect, however, n can have an upper limit. For example, n can be from about 1 to about 1000, from about 1 to about 500, from about 1 to about 250, from about 1 to about 200, from about 1 to about 200, from about 1 to about 150, from about 1 to about 100, or from about 1 to about 50, and, depending on the polydispersity of the polymer, any combination thereof. In a further aspect, n is within the range of about 10 to about 100,000, of about 100 to about 10,000, of about 1,000 to about 10,000, of about 2 to about 10, or even of about 5 to about 20.

Referring now to FIG. 7, a non-limiting embodiment of a class of materials in accordance with the present disclosure is depicted. Notably, these materials can contain three main components: a polymerizable portion (shown here as bis-thiophene moieties), a chelating agent for the lanthanide (which, in this embodiment, includes a variety of dinitrogen donors), and the lanthanide itself (europium), which forms the emitting material.

It is understood that the symbol [symbol] is intended to refer to an optional bond, and such a bond can be represented in a structural formula as:

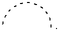

In one aspect, wherein [symbol] is present, at least one of R¹ and R², or R³ and R⁴, or R⁵ and R⁶, or R⁷ and R⁸, or a combination thereof, together form a structure represented by the formula:

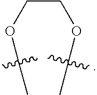

In one aspect, a disclosed light-emitting device can comprise a lanthanide element complex bound to an electrically conducting polymer. Such a material can be synthesized, for example, through the use of specifically designed ligands that can both bind a lanthanide element center and undergo polymerization.

In one aspect, a disclosed electrically conductive polymer can comprise one or more ligands which can bind one or more lanthanides. Any ligand suitable to bind a lanthanide element is contemplated for use with the disclosed materials. For example, in one aspect, a ligand having a structure represented by the formula:

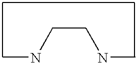

is present as:

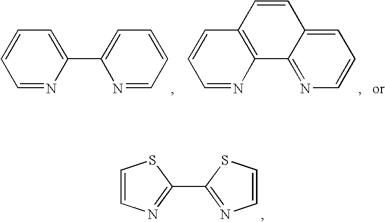

or a combination thereof.

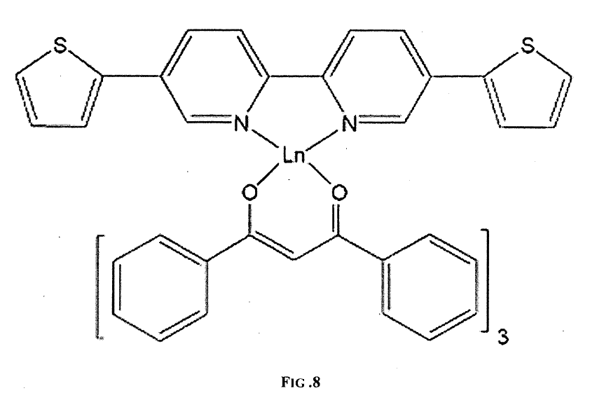

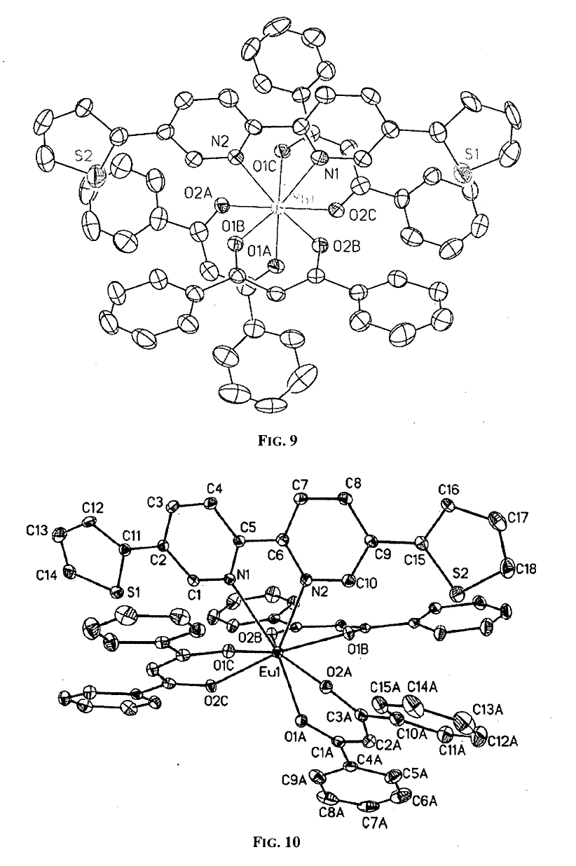

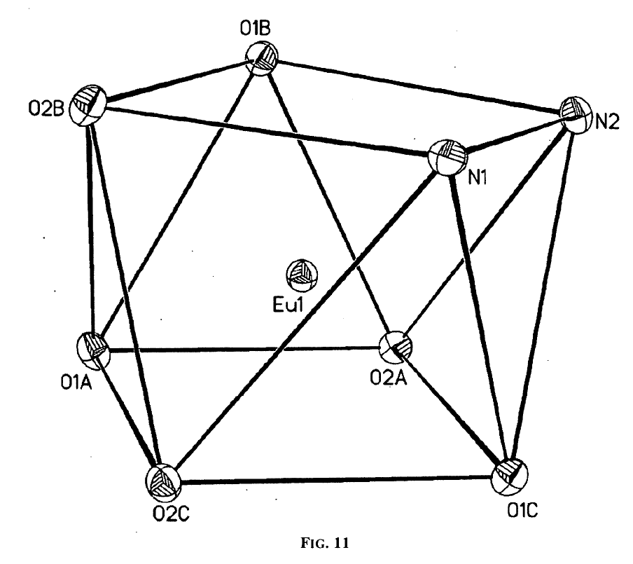

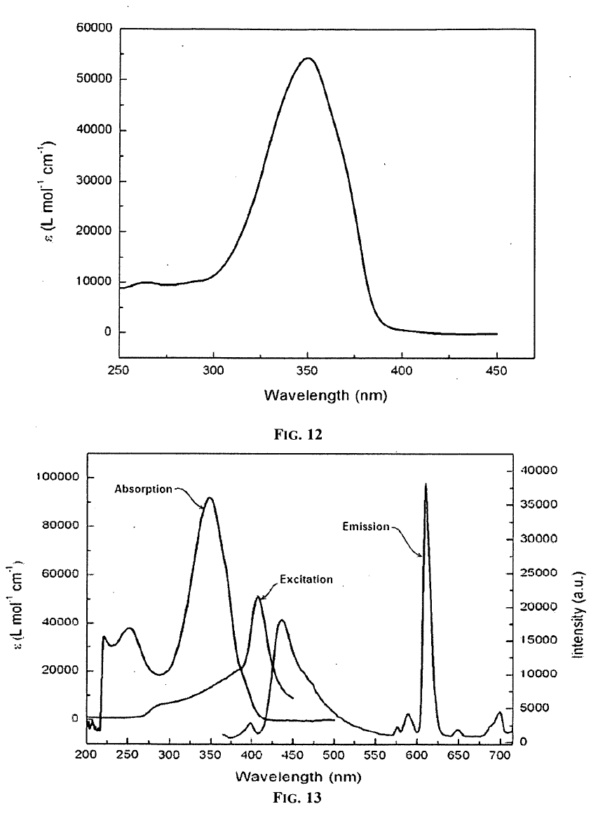

FIG. 8 depicts a non-limiting class of a disclosed material, wherein a BPY ligand is present. A BPY (2,2′-bipyridyl) dinitrogen donor which can be flanked by thiophene moieties, which can be the polymerizable portion of the material. FIG. 9 depicts the crystal structure of an exemplary Yb species of the class of materials shown in FIG. 8. Likewise, FIGS. 10-11 depict the crystal structure and binding environment of an exemplary europium species of the class of compounds shown in FIG. 8. FIG. 12 depicts the UV visible absorption spectrum of the material of FIG. 8 (wherein Ln=Eu) in solution (CH₂Cl₂) at room temperature. FIG. 13 shows the emission profile of the material in solution and the excitation profile. As shown, the material provides a sharp emission peak at about 614 nm. The sharpness of this peak can be differentiated from the broader peak appearing at 450 nm, which arises from standard organic fluorescence. Table 1 summarizes crystal data (including Ln-O and Ln-N bond lengths) and photo physics (including the adsorption (ε) and quantum yield QY)) of various lanthanide species of the class of material depicted in FIG. 8.

TABLE 1
Properties of materials of FIG. 8.

| Complex | Sm | Eu | Gd | Tb | Dy | Yb |
|---|---|---|---|---|---|---|
| Ln-O (Å) | — | 2.3443(18) | — | 2.319(2) | — | 2.269(4) |
| Ln-N (Å) | — | 2.6205(2) | — | 2.593(3) | — | 2.539(4) |
| ε (10⁴ L · | 9.66 | 9.15 | 10.27 | 10.2 | 9.43 | 9.47 |
| mol⁻¹ · | | | | | | |
| cm⁻¹) | | | | | | |
| QY (%) | — | 1.8 | — | — | — | — |

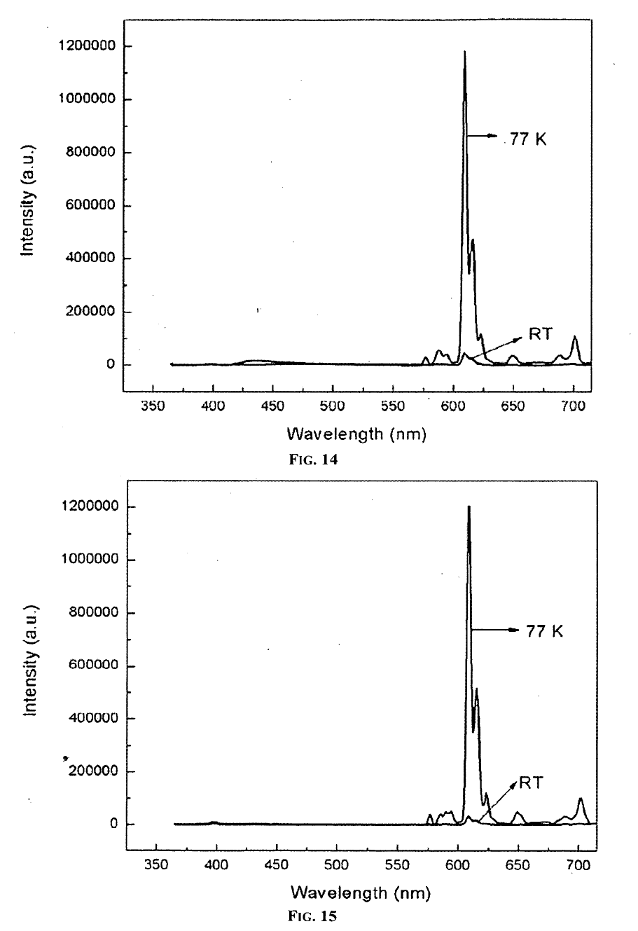

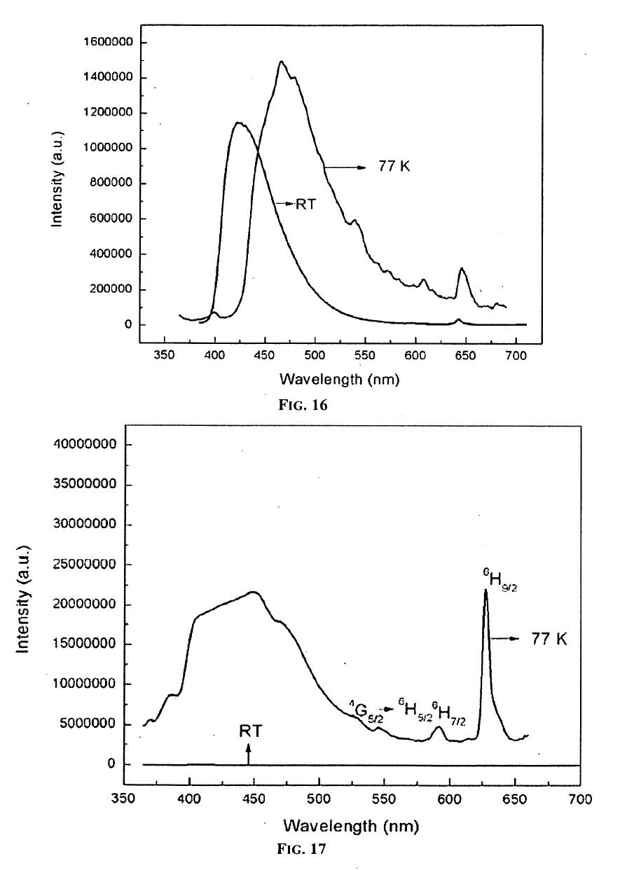

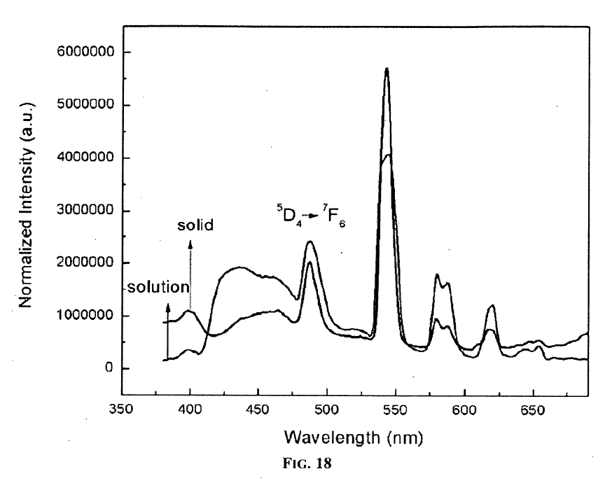

FIG. 14 depicts the emission spectrum of the material of FIG. 8 (wherein Ln=Eu) in toluene at room temperature and at 77K. FIG. 15 depicts the emission spectrum of this material in a frozen (i.e., solid) state. As shown, in one aspect, at cooler temperatures, the emission spectrum of the material can be cleaner, e.g., sharper (i.e., wherein the width of the emission peak at half the height of the peak is smaller than a reference emission peak) than it is at room temperature and at 77K. FIG. 16 depicts the emission spectrum of the material of FIG. 8 (wherein Ln=Sm) in toluene at room temperature. FIG. 17 depicts the emission spectrum of this material in a frozen (i.e., solid) state. Again, as shown, at cooler temperatures, the emission spectrum of the material can be cleaner than it is at room temperature. FIG. 18 depicts the emission spectrum of the material of FIG. 8 (wherein Ln=Tb) in toluene, both at room temperature and in a frozen (i.e., solid) state.

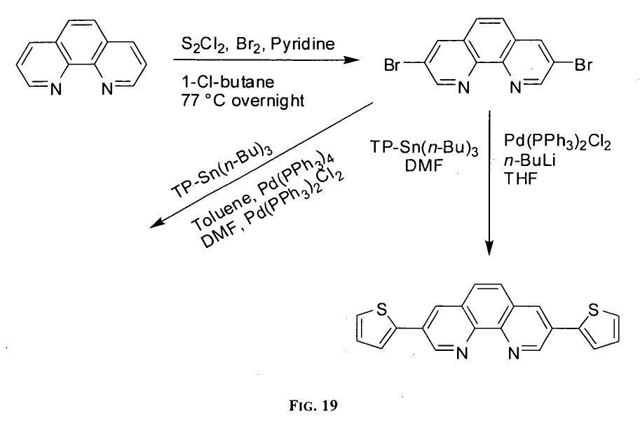

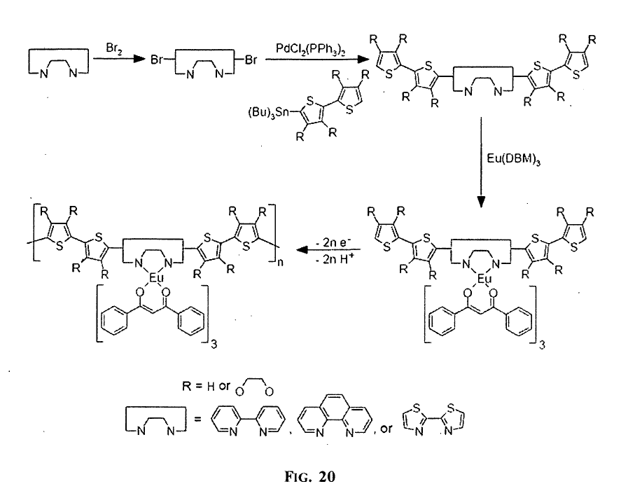

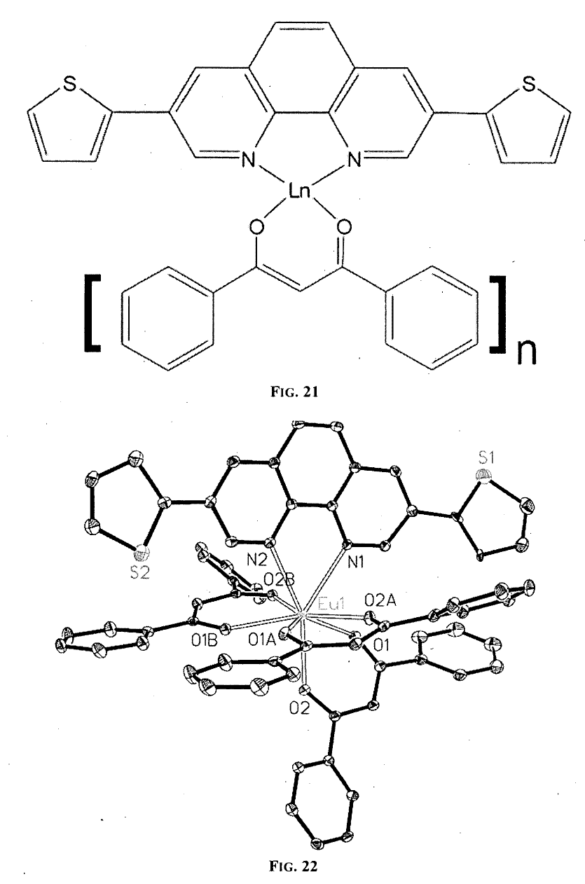

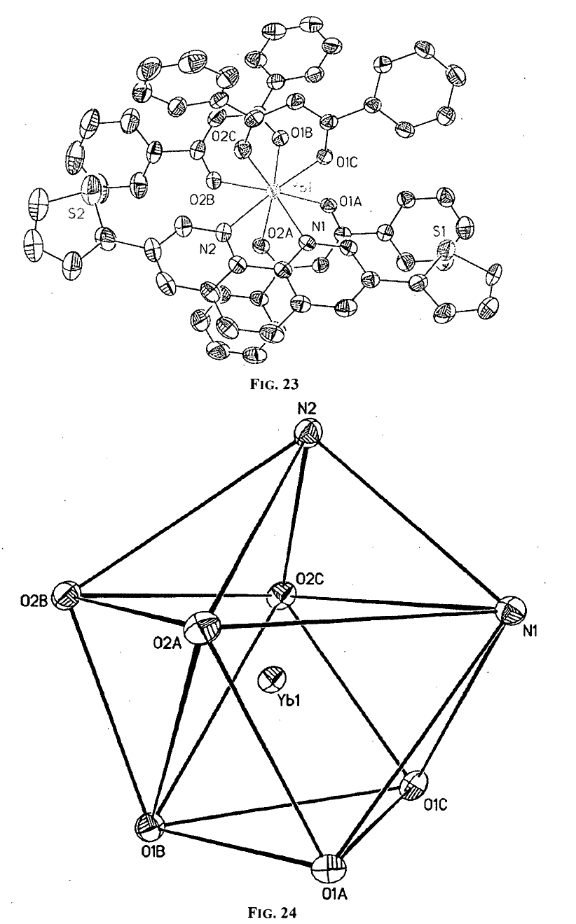

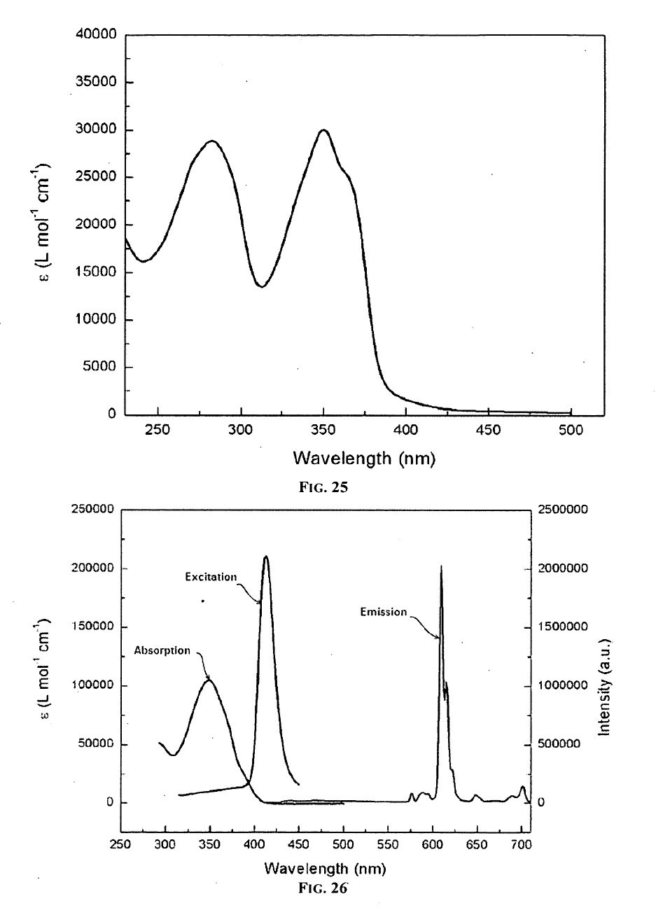

Ligands can be produced by methods known in the art. For example, FIG. 19 summarizes an example of a suitable synthetic route that can be utilized to produce a phenanthroline (PHEN) ligand flanked by thiophene moieties. Once produced, the ligand can be reacted with lanthanides to produce PHEN analogs of the electrically conductive monomers shown in the synthetic scheme of FIG. 20, and these monomers can be electrochemically polymerized. FIG. 21 illustrate specific exemplary PHEN monomers that can be provided by this scheme, and FIG. 22 shows the X-ray crystal data for the Eu species thereof. FIGS. 23-24 illustrate the crystal data for the Yb species of the PHEN monomer depicted in FIG. 21 (for Ln=Yb). FIG. 25 depicts the UV visible absorption spectrum of the material of FIG. 21 (wherein Ln=Eu) in solution (toluene) at room temperature. FIG. 26 shows the emission profile of the material in solution and the excitation profile. As shown, the material can provide a sharp emission peak at about 614 nm. Table 2 summarizes some crystal data (including Ln-O and Ln-N bond lengths) and photo physics (including the adsorption (ε) and quantum yield QY)) of various lanthanide species of the class of material depicted in FIG. 21. Notably, the quantum yield of the Eu PHEN analog showed an increase over the value observed for the Eu BPY analog.

TABLE 2
Properties of materials of FIG. 21.

| Complex | Sm | Eu | Gd | Tb | Dy | Yb |
|---|---|---|---|---|---|---|
| Ln-O (Å) | — | 2.363(3) | — | — | — | 2.267(2) |
| Ln-N (Å) | — | 2.639(4) | — | 2.593(3) | — | 2.540(2) |
| ε (10⁴ L · | 10 | 10.22 | 8.29 | 8.13 | 9.87 | 9.24 |
| mol⁻¹ · | | | | | | |
| cm⁻¹) | | | | | | |
| QY (%) | — | 2.11 | — | — | — | — |

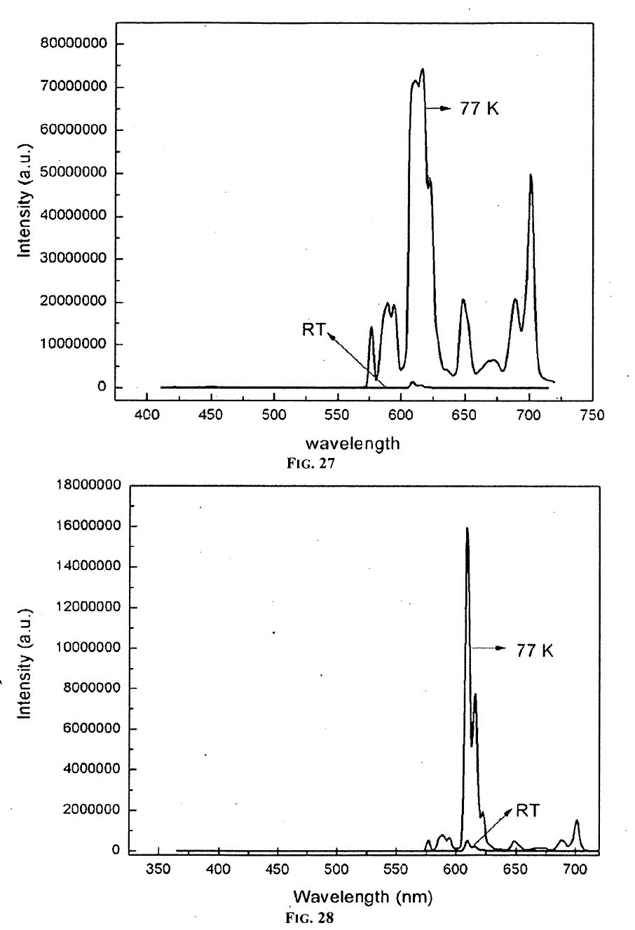

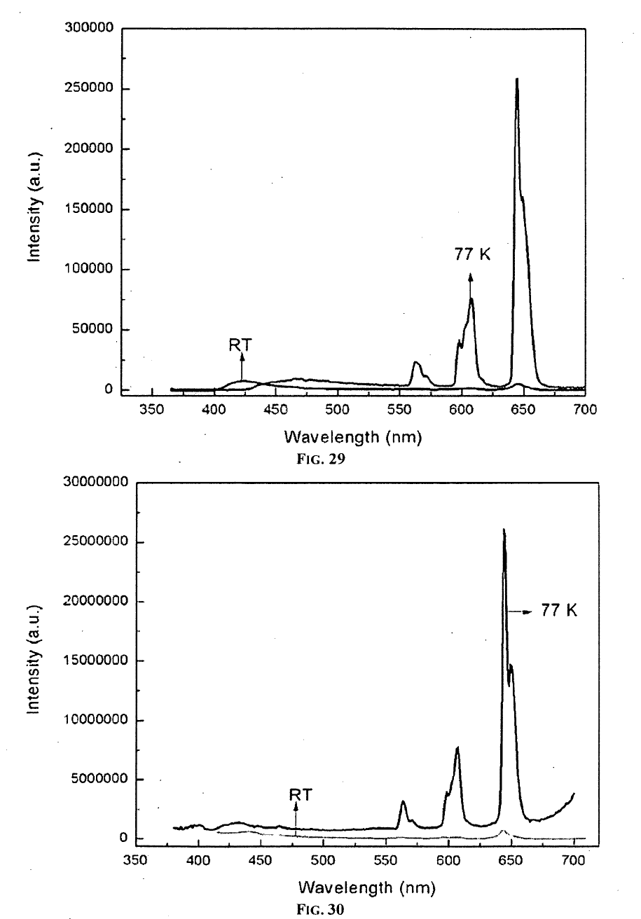

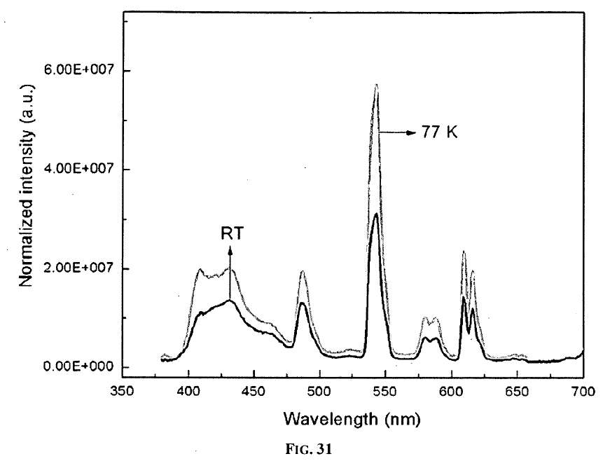

FIG. 27 depicts the emission spectrum of the material of FIG. 21 (wherein Ln=Eu) in 1,2-dichlorobenzene (DCB) at room temperature. FIG. 28 depicts the emission spectrum of this material in a frozen (i.e., solid) state. As seen therein, at cooler temperatures, the emission spectrum of the material can be cleaner, e.g., sharper, than it is at room temperature.

FIG. 29 depicts the emission spectrum of the material of FIG. 21 (wherein Ln=Sm) in toluene at room temperature. FIG. 30 depicts the emission spectrum of this material in a frozen (i.e., solid) state. Again, as shown, at cooler temperatures, the emission spectrum of the material is cleaner than it is at room temperature.

FIG. 31 depicts the emission spectrum of the material of FIG. 21 (wherein Ln=Tb) in toluene, both at room temperature and in a frozen (i.e., solid) state.

In one aspect, wherein a dinitrogen donor ligand is present in a disclosed material, the electrically conductive oligomer, polymer, or combination thereof can have a structure represented by a formula:

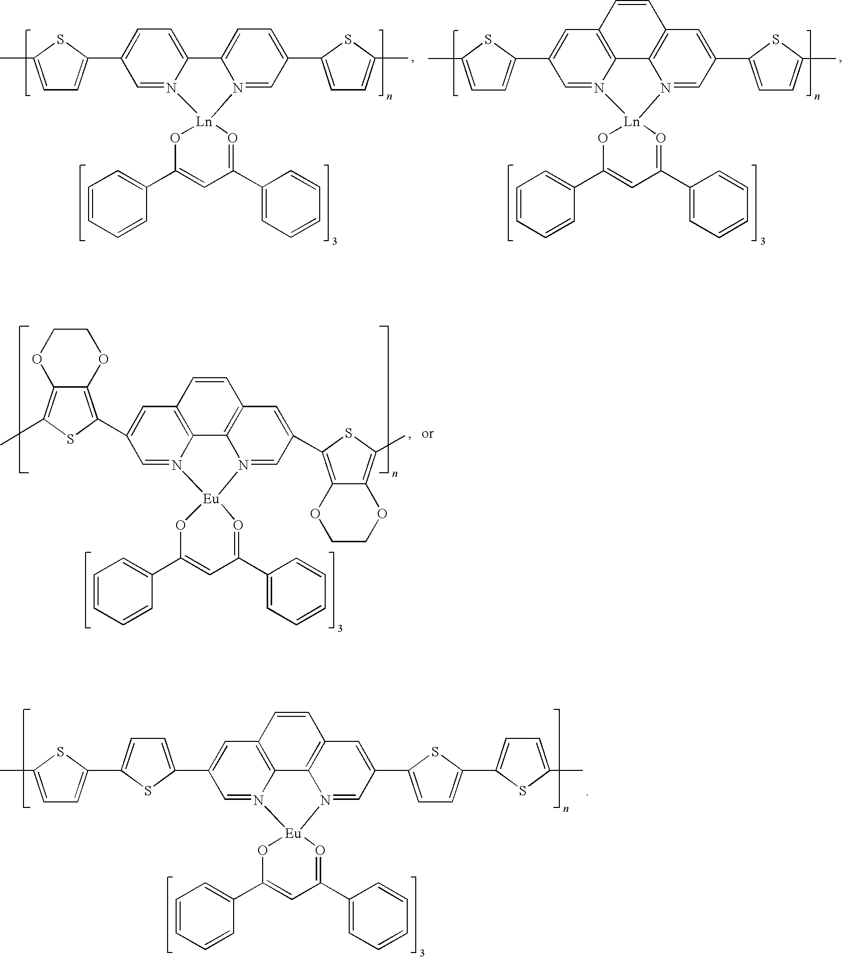

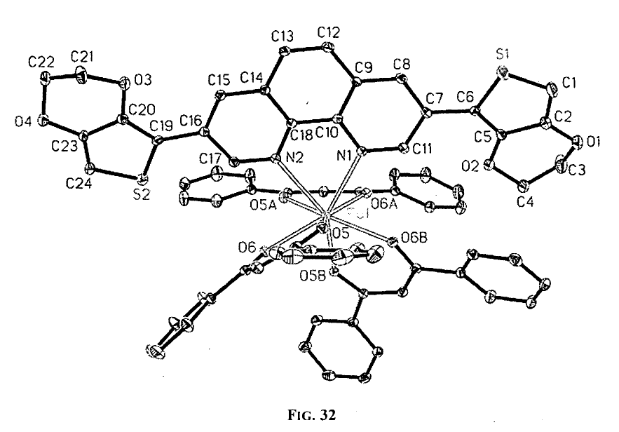

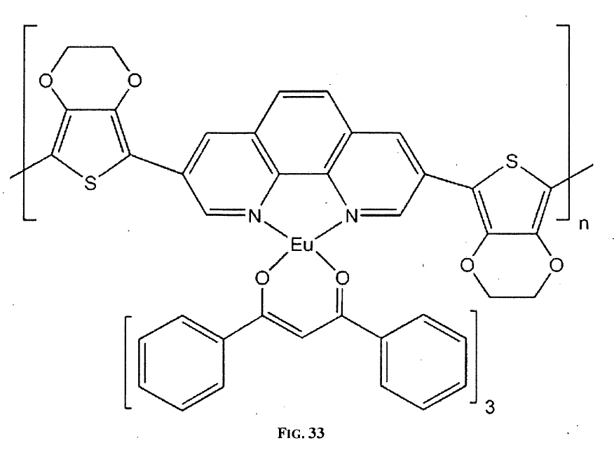

For example, with reference to FIGS. 32-33, a class of materials can be provided using phenanthroline as the ligand and using 3,4-ethylenedioxythiophene (EDOT) as the polymerizable moiety. The bond length data for some of these materials is shown in Table 3. In this example, the incorporation of a 1,4-dioxane ring into the thiophene moiety was found to lower the oxidation potential of the thiophene ring and make it easier to polymerize.

TABLE 3
Bond length data for materials in FIG. 33

Bond Length (Å)

| Complex | Ln-O | Ln-N |
|---|---|---|
| Nd(DBM)₃[(EDOT)₂Phen] | 2.340(18) | 2.682(2) |
| Eu(DBM)₃[(EDOT)₂Phen] | 2.329(3) | 2.577(4) |
| Dy(DBM)₃[(EDOT)₂Phen] | 2.318(3) | 2.574(3) |
| Yb(DBM)₃[(EDOT)₂Phen] | 2.276(3) | 2.531(3) |

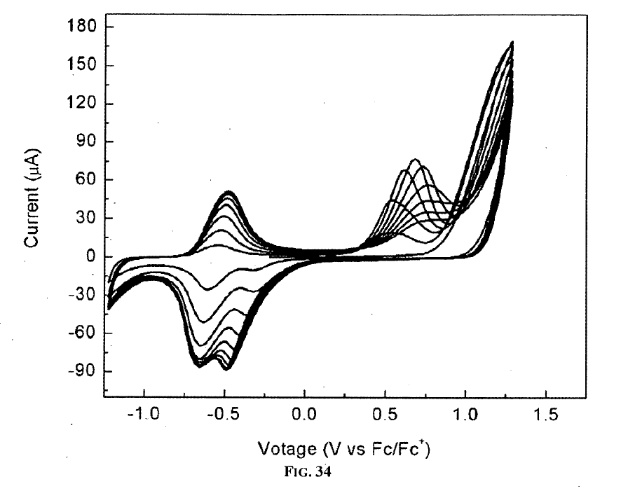

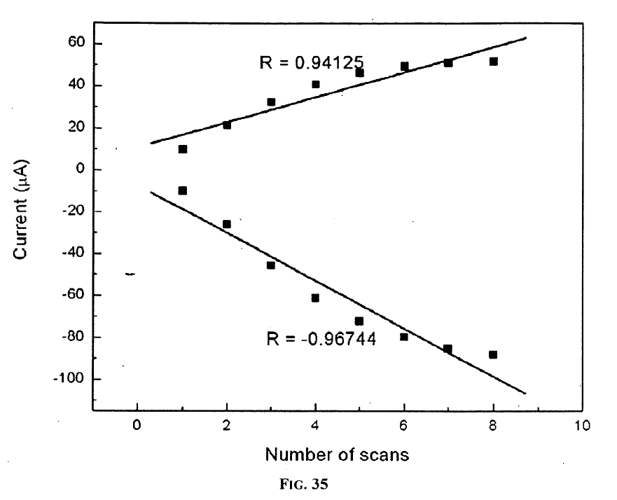

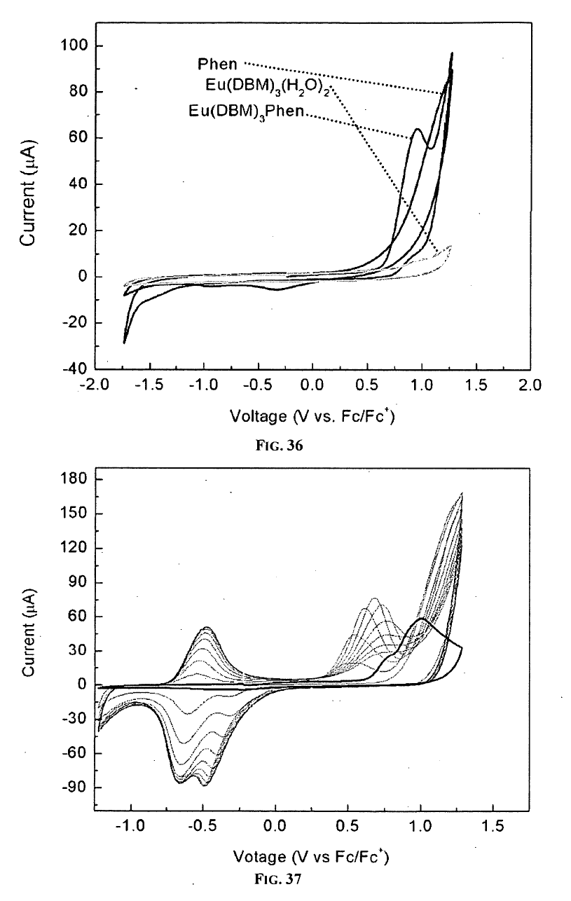

FIGS. 34-35 show electrodeposition results achieved with the europium monomer shown in FIG. 33. These results were obtained by running the material through cyclic voltammetry, which oxidizes and polymerizes the monomer. As a result, a thin film of the polymer can be grown a layer at a time.

Electrochemistry of a disclosed material can be characterized by methods known in the art, such as, for example, by cyclic voltammetry. FIG. 36 shows the electrochemistry of some model compounds. These studies were done to ensure that the oxidation observed in the materials being tested arises from electropolymerization rather than from oxidation of an impurity. The scans in the chart correspond to phenanthroline by itself, Eu(DBM)₃(H₂O)₂ (that is, the metal species) by itself, and the third is Eu(DBM)₃Phen by itself (that is, the portion of the monomer without the polymerizable moieties). In FIG. 37, these scans are then juxtaposed against the results achieved during the polymerization of the material of FIG. 39. As seen from the figure, all of the oxidations observed during polymer growth are all unique to the monomer.

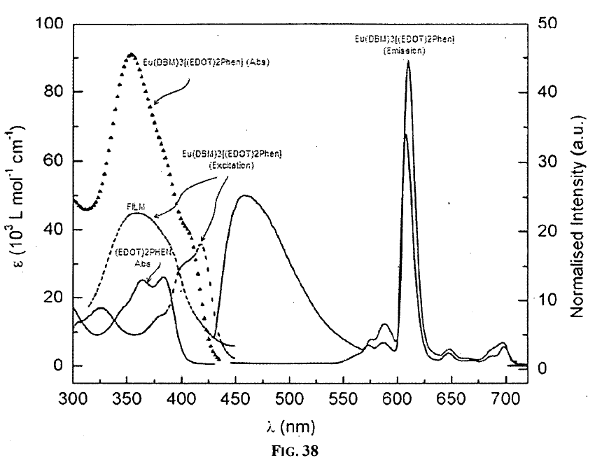

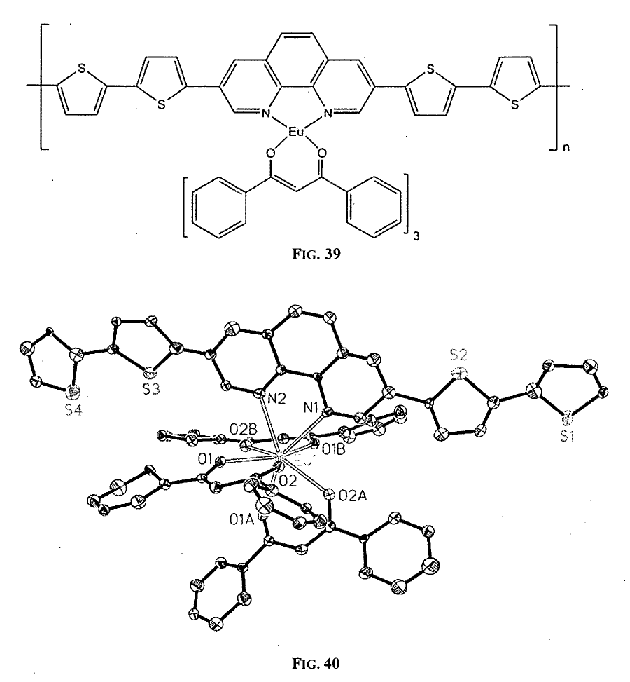

A disclosed oligomer or polymer can, in some aspects, exhibit different properties than a monomer from which the oligomer or polymer was produced. Referring to FIG. 38, some fluorescence from the ligand occurs in material at about 475 nm, and a sharp lanthanide emission occurs at about 614 nm. The monomer is then polymerized through the process shown in FIGS. 34-35 to make a thin film, the scan of which is indicated by the bold peripheral line. Upon polymerization of the material, the fluorescence disappears, thus demonstrating the excellent color purity which can be obtained with these materials. FIG. 38 also includes adsorption spectra and excitation spectra. These spectra demonstrate that the organic portion of the material is absorbing light, and that the material is undergoing a cascade (of the type indicated in FIG. 2) to ultimately lead to lanthanide emissions.

FIG. 39 represents a further particular, non-limiting class of compounds made in accordance with the present disclosure, a crystal structure of which is shown in FIG. 40. The materials shown feature a thiophene residue as the polymerizable moiety. TABLE 4 shows the bond length data for these materials.

TABLE 4
Bond length data for materials of FIG. 39

Bond Length (Å)

| Complex | Ln-O | Ln-N |
|---|---|---|
| Sm(DBM)₃[(BT)₂Phen] | 2.378(10) | 2.633(12) |
| Eu(DBM)₃[(BT)₂Phen] | 2.382(13) | 2.642(15) |
| Gd(DBM)₃[(BT)₂Phen] | 2.343(12) | 2.582(14) |
| Tb(DBM)₃[(BT)₂Phen] | 2.342(7) | 2.611(8) |
| Dy(DBM)₃[(BT)₂Phen] | 2.318(18) | 2.622(15) |
| Er(DBM)₃[(BT)₂Phen] | 2.305(9) | 2.585(12) |

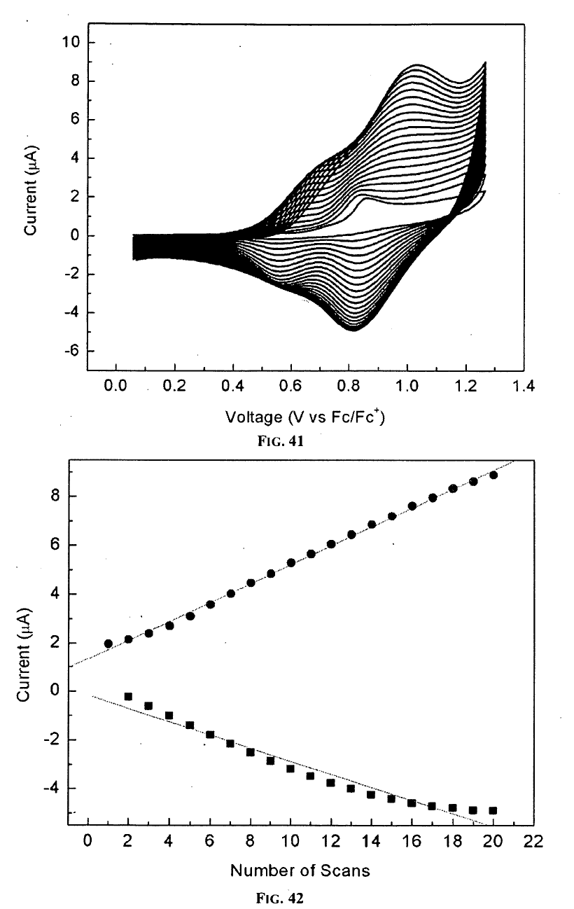

FIGS. 41-42 show electrodeposition results achieved with the Europium monomer shown in FIG. 39. These results were obtained by running the material through cyclic voltammetry, which oxidizes and polymerizes the monomer. As a result, a thin film of the polymer is grown a layer at a time.

Also included within the disclosed compounds are derivatives of the compounds, including, for example, hydrates, or solvent complexed derivatives of the disclosed compounds.

In one aspect, a disclosed monomer can be used to provide a disclosed oligomer or polymer. In one aspect, a disclosed monomer can be a compound having a structure represented by a formula:

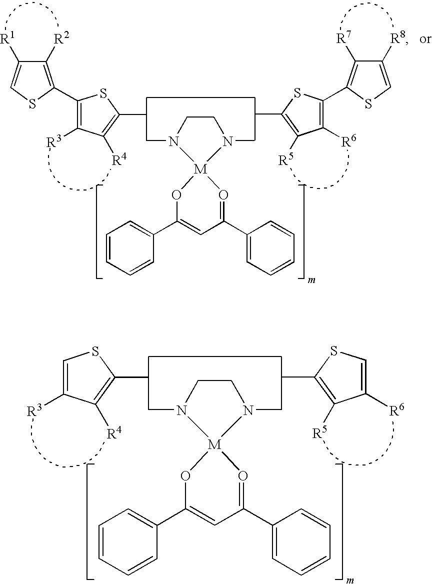

wherein m is an integer from 1 to 3; wherein M is a lanthanide element is present as lanthanum, cerium, praseodymium, neodymium, promethium, samarium, europuum, gadolinium, terbium, dysprosium, holmium, erbium, thulium, ytterbium, lutetium; wherein R¹ (when present), R² (when present), R³, R⁴, R⁵, R⁶, R⁷(when present), and R⁸(when present) are hydrogen, or an optionally substituted organic residue comprising from 1 to 8 carbons; wherein [symbol] is an optional bond; wherein

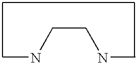

is present as an optionally substituted aryl or optionally substituted heteroaryl residue;

In one aspect, wherein [symbol] is present, at least one of R¹ and R², or R³ and R⁴, or R⁵ and R⁶, or R⁷ and R⁸, or a combination thereof, together form a structure represented by the formula:

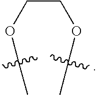

D. Methods

The disclosed monomers, oligomers, and polymers can be made by methods known in the art, or by methods presently disclosed. As an example, a thiophene based polymer can be provided according to the scheme summarized in FIG. 20. The first two steps of the synthetic scheme can involve the synthesis of the ligand, and the third step can involve the introduction of a lanthanide element or a platinum group metal, which can bind to the two nitrogen atoms of the ligand; the fourth step can involve electro-polymerization.

In a further aspect, these materials can be polymerized into thin films. The resulting thin films can be photoluminescent (that is, when light impinges on the conductive polymer backbone, excited states are generated, resulting in energy transfer to the lanthanide such that the only or principle light emitted from the material is from the lanthanide emission). It will apparent that the light emitted by these materials can be sharp and monochromatic.

In one aspect, disclosed are methods for making the disclosed materials and devices. For example, a disclosed method for producing a polymeric light-emitting device can comprise the steps of: providing at least one electrode with at least one monomer positioned thereon; and polymerizing the at least one monomer to provide a polymeric layer; wherein the at least one monomer and polymeric layer produced therefrom comprises at least one of a lanthanide element, a platinum group metal, or a combination thereof, and wherein the polymeric layer is electrically conductive; thereby producing the polymeric light-emitting device.

In one aspect, polymerizing the at least one monomer comprises electropolymerization. An exemplary electropolymerization step is shown in FIG. 20. Any means of electropolymerization can be employed. For example, an oxidizing or reducing agent can be used. In the alternative, a current can be applied to a monomer deposited on a substrate, thereby polymerizing the monomer and forming a thin film. It will be apparent, however, that methods for making the disclosed oligomers and polymers are not limited to electropolymerization. Other methods, such as radical polymerization, can be used.

In one aspect, the polymeric layer comprises at least two polymeric film layers, wherein the at least two polymeric film layers are provided in a step-wise fashion. For example, a monomer deposited onto a substrate can be polymerized. Then, an additional monomer layer can be applied. Subsequently the second monomer can be polymerized as in the first step. Such a sequence can be repeated until a desired film or layer property is achieved, such as, for example, a desired thickness.

In one aspect, a device can be provided through a “bottom-up” approach. Thus, in one aspect, the at least one electrode is an anode. In a further aspect, producing the polymeric light-emitting device further comprises providing a cathode positioned on at least a portion of the polymeric layer, such that the anode and the cathode have at least a portion of the polymeric layer positioned therebetween.

A disclosed material can be used in a variety of applications, such as, for example, applications where visible and near-infrared light emission is desired. These applications include, but are not limited to, the use of these materials in hybrid, organic, and polymer light-emitting diodes, their use in flexible screens and displays, their use in chemical sensors, their use in chemical taggants, and their use in communications applications. Moreover, a disclosed method can be used to make electroluminescent materials for a variety of applications, including those aforementioned.

### E. Examples

The following examples are put forth so as to provide those of ordinary skill in the art with a complete disclosure and description of how the compounds, compositions, articles, devices and/or methods claimed herein are made and evaluated, and are intended to be purely exemplary of the invention and are not intended to limit the scope of what the inventors regard as their invention. Efforts have been made to ensure accuracy with respect to numbers (e.g., amounts, temperature, etc.), but some errors and deviations should be accounted for. Unless indicated otherwise, parts are parts by weight, temperature is in° C. or is at ambient temperature, and pressure is at or near atmospheric.

1. Materials and General Methods

Unless otherwise noted, all reactions and manipulations were carried out under nitrogen using standard Schlenk techniques or in an inert-atmosphere glove box. Methylene chloride, hexanes, and diethyl ether were dried using a double-column anhydrous solvent system (Innovative Technologies, Newburyport, Mass.) and further degassed via nitrogen purge prior to use. Deuterated solvents were purchased from Cambridge Isotope Laboratories and used without further purification. All other chemicals were purchased from commercial sources and used as received. Elemental analysis was performed by QTI, Whitehouse, N.J.

A. Instrumentation

NMR spectra were recorded on a Varian 400 NMR Spectrometer with an Oxford Instruments Ltd. superconducting magnet using a Sun Ultra 5 workstation and a 5 mm Autoswitchable probe (¹H/¹⁹F/¹³C/³P). ¹H NMR signals were recorded relative to residual proton resonances in deuterated solvents. All NMR resonances were recorded in ppm, and coupling constants were calculated in Hz. ¹³C{¹H} NMR spectra were recorded at 75 Mhz and referenced relative to solvent peaks. Mass spectra were recorded on one of two high-resolution magnetic sector mass spectrometers (Micromass ZAB and Autospec) equipped with EI, CI, FAB, in positive/negative ionization modes. Melting points were recorded on a Mel-Temp II melting temperature apparatus made by Laboratory Devices of Holliston, Mass. UV-vis data was recorded on either a Varian/Cary 5000 or a Varian/Cary 6000i spectrophotometer. Luminescence data was recorded on a Horiba Jobin-Yvon/Spex Fluorolog-3 fluorescence spectrophotometer.

B. Electrochemistry Methods

Electrochemical measurements were performed using an Autolab PGStat-30 potentiostat with bipotentiostat and impedance spectroscopy modules. Unless otherwise noted all experiments were carried out using a three electrode system with a Pt button working electrode, Ag/AgNO₃ non-aqueous reference electrode, and a Pt wire coil counter electrode (all from Bioanalytical Systems, Inc.; www.bioanalytical.com). Ferrocene was used as an external reference to calibrate the reference electrode before and after experiments were performed and that value was used to correct the measured potentials. The supporting electrolyte was 0.1 M [(n-Bu)₄N][PF₆](TBAPF₆) that was purified by recrystallization three times from hot ethanol before being dried for 3 days at 100-150 EC under active vacuum.

2. Synthesis of 3,8-bis(3,4-(Ethylenedioxy)Thien-2-YL)-1,10-Phenanth-Roline.

A solution of Pd(II)(PPh₃)₂Cl₂ (0.31 g, 0.44 mmol) in 5 mL of dry THF was cooled in a dry ice/acetone bath, and n-butyllithium (550 μL of a 1.6 M solution in hexane). The cooling bath was removed after stirring for 20 min. When it reached the room temperature, the yellow mixture turned into a clear dark blue solution. The above solution was transferred by a cannula to a solution of 3,8-dibromo-1,10-phenanthroline (1.56 g, 4.6 mmol) and 2-(tributylstannyl)-3,4-(ethylenedioxy)thiophene (4.64 g, 10.8 mmol) in 60 mL of dry DMF. The reaction mixture was heated for 15 h at 130° C. After cooling, 100 mL of CH₂Cl₂ was added into the resulting red solution. The solution was then washed with saturated NH₄Cl and H₂O. The separated organic phase was evaporated to get the crude residue. Ethyl acetate (100 mL) was added to the above residue to get a yellow solid, which was filtered (yield 1.14 g, 53%). The product was characterized by ¹H and ¹³C{1H} NMR spectroscopy and mass spectrometry.

3. Synthesis of Eu(DBM)₃[(EDOT)₂Phen] (1).

Eu(DBM)₃(H₂O)₂ was prepared by a literature method (Charles, R. G.; Perrotto, A. J. Inorg. Nucl. Chem. 1964, 26, 373). Eu(DBM)₃(H₂O)₂ (42.9 mg, 0.05 mmol) was added into a suspension of (EDOT)₂Phen (23.0 mg, 0.05 mmol) in toluene (5 mL). The mixture was refluxed for half an hour to get a clear yellow solution. After filtration, the solution was slowly cooled to room temperature and stored at the refrigerator. Yellow crystals (24.6 mg, yield 34%) suitable for X-ray diffraction analysis were obtained after a few days. The product was characterized by ¹H NMR spectroscopy and mass spectrometry.

3. Synthesis of an Exemplary Platinum Group Metal Complex and Polymer Thereof.

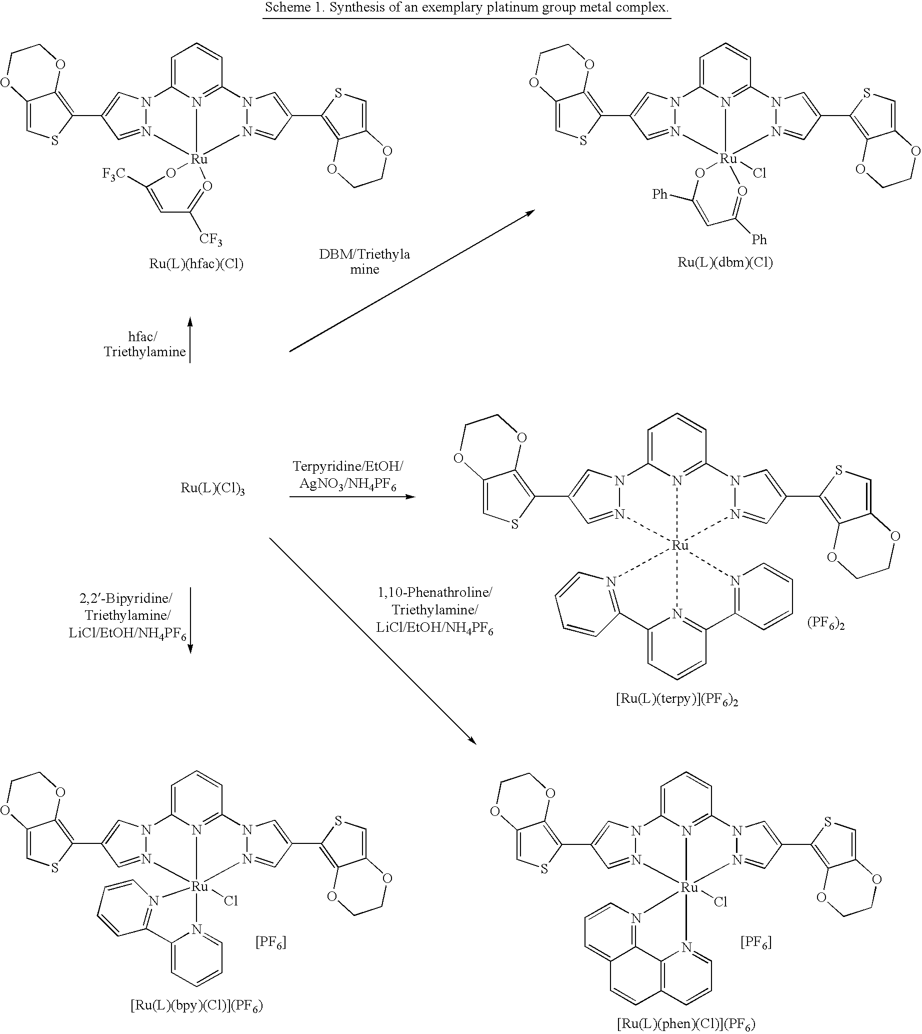

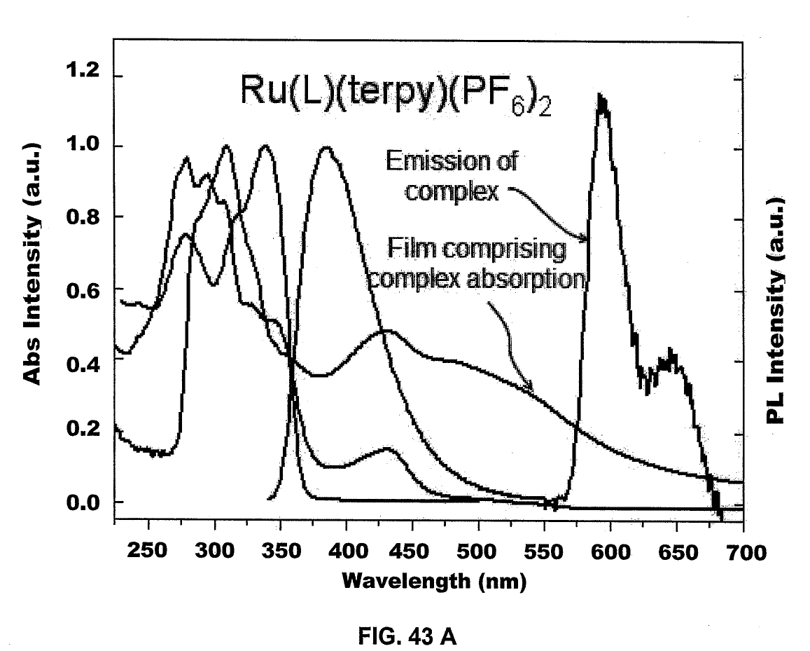

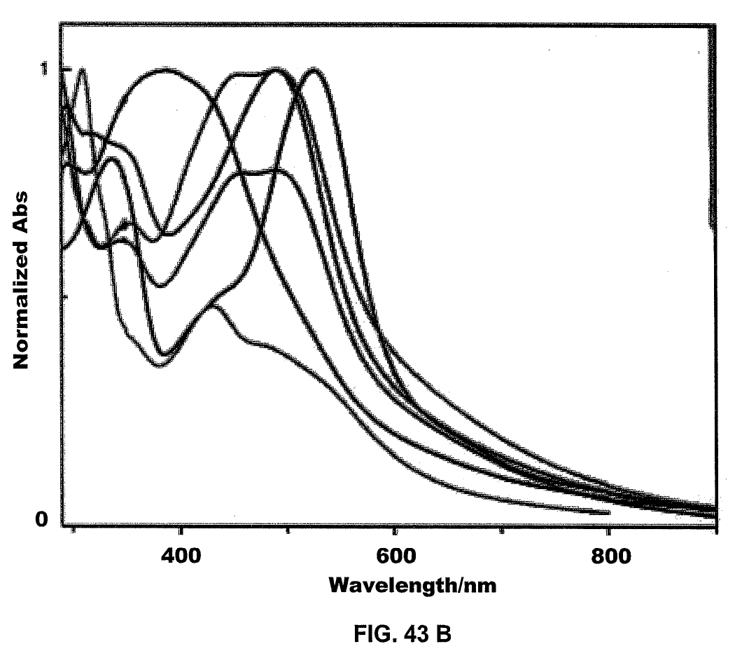

In one aspect, a disclosed class of materials can be luminescent, e.g., fluorescent and/or phosphorescent. For example, a disclosed class of Ru complexes, and discussed further herein, can exhibit photophysical properties according to FIG. 43.

3. Synthesis of an Examplary Platinum Monomer.

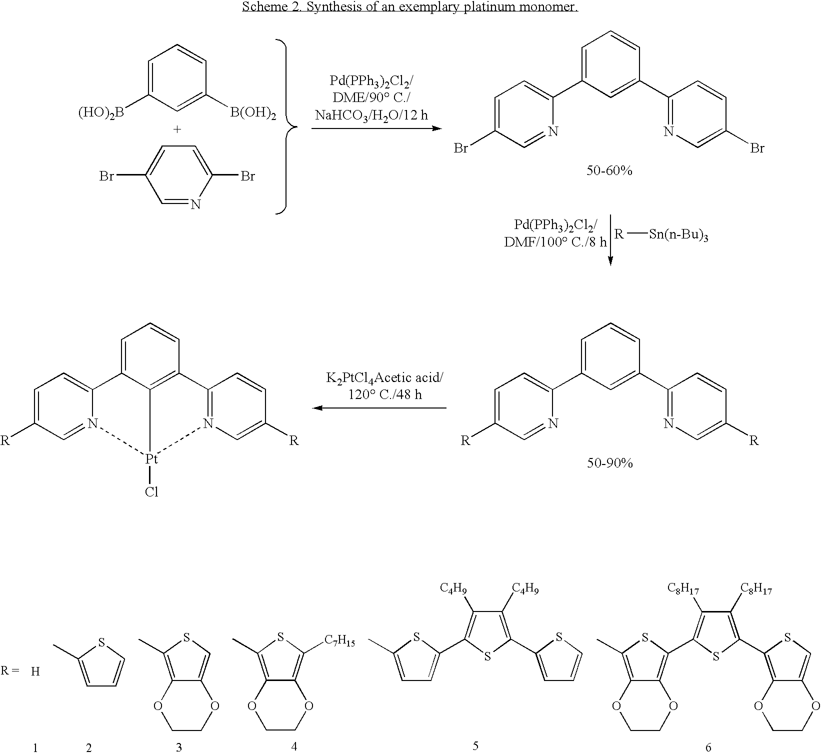

A monomer provided according to Scheme 2 can be electropolymerized, for example, to provide a polymer having a structure represented by a formula:

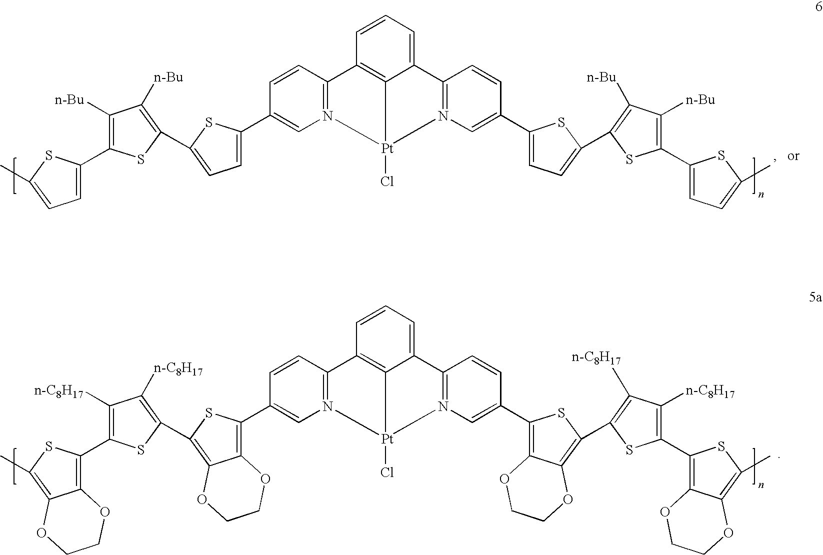

It will be apparent to those skilled in the art that various modifications and variations can be made in the present invention without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A light-emitting device comprising: an at least partially electrically conductive oligomer, polymer, or a combination thereof comprising at least one of a lanthanide element, a platinum group metal, or a combination thereof.

2. The device of claim 1, comprising at least one lanthanide element.

3. The device of claim 1, comprising at least one platinum group metal.

4. The device of claim 2, wherein the at least one lanthanide element is in electronic communication with the at least partially electrically conductive oligomer, polymer, or a combination thereof.

5. The device of claim 2, wherein the at least one lanthanide element is present in a complex that is bonded to the oligomer, polymer, or combination thereof through at least one covalent, electrostatic, ionic, or dative bond.

6. The device of claim 2, wherein the at least one lanthanide element is present in a complex that is covalently bonded to the oligomer, polymer, or combination thereof, and
wherein the oligomer, polymer, or combination thereof comprises at least two conjugated π bonds.

7. The device of claim 1, wherein the device comprises an anode, a cathode, and a light-emitting layer positioned therebetween, wherein the light-emitting layer comprises the at least partially electrically conductive oligomer, polymer, or a combination thereof.

8. The device of claim 7, wherein the oligomer, polymer, or combination thereof functions as at least two of a light emissive material, a hole transport material, and/or an electron transport material.

9. The device of claim 7, wherein the device does not comprise a distinct electron transport and hole transport layer.

10. The device of claim 1, wherein the device comprises a layered structure comprising an anode, a cathode, and a light-emitting layer at least partially therebetween; and
wherein the light-emitting layer comprises the at least partially electrically conductive oligomer, polymer, or a combination thereof.

11. The device of claim 1, wherein the oligomer, polymer, or combination thereof has a structure represented by a formula: 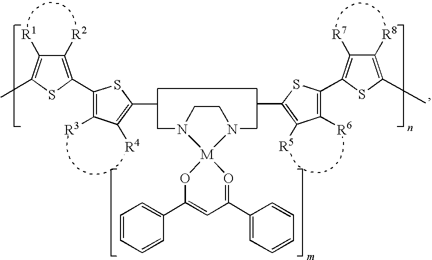
wherein m is an integer from 1 to 3;
wherein n≧1;
wherein M comprises a lanthanide element, a platinum group metal, or a combination thereof;
wherein R¹, R², R³, R⁴, R⁵, R⁶, R⁷, and R⁸ are hydrogen or an optionally substituted organic residue comprising from 1 to 8 carbons; wherein [symbol] is an optional bond; and
wherein 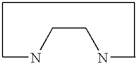
is present as an optionally substituted aryl or optionally substituted heteroaryl residue.

12. The device of claim 11, wherein M comprises a lanthanide element.

13. The device of claim 11, wherein [symbol] is present; and
wherein at least one of R¹ and R², or R³ and R⁴, or R⁵ and R⁶, or R⁷ and R⁸, or a combination thereof, together form a structure represented by the formula:

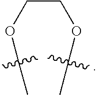

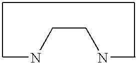

14. The device of claim 11, wherein comprises:

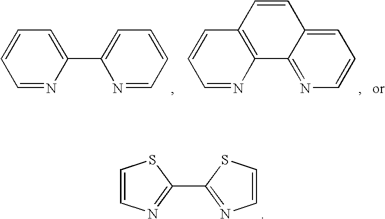

15. The device of claim 1, wherein the at least partially electrically conductive oligomer, polymer, or a combination thereof has a structure represented by a formula:

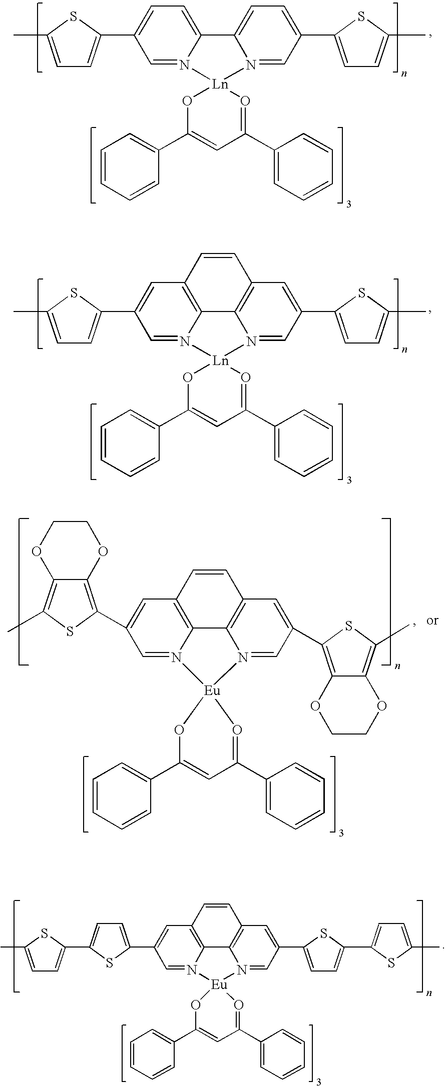

16. The device of claim 1, wherein the at least partially electrically conductive oligomer, polymer, or a combination thereof has a structure represented by a formula:

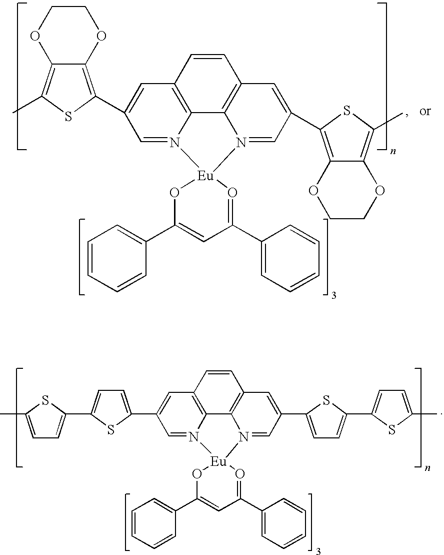

17. A compound having a structure represented by a formula: 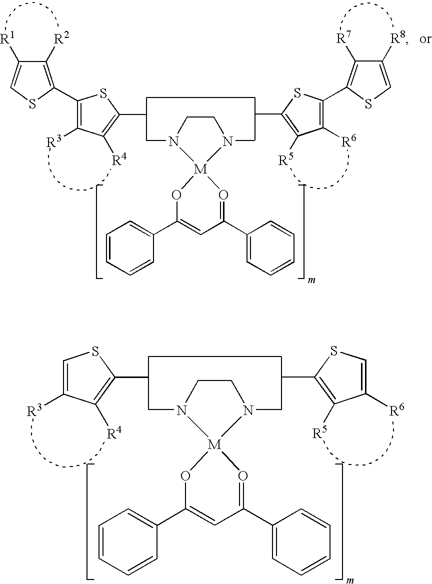
wherein m is an integer from 1 to 3;
wherein M is a lanthanide element, a platinum group metal, or a combination thereof,
wherein R¹, if present, R², if present, R³, R⁴, R⁵, R⁶, R⁷, if present, and R⁸, if present, are hydrogen or an optionally substituted organic residue comprising from 1 to 8 carbons; wherein [symbol] is an optional bond; and
wherein 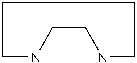
is present as an optionally substituted aryl or optionally substituted heteroaryl residue,
or an oligomer or polymer produced therefrom.

18. The compound of claim 17, wherein [symbol] is present; and
wherein at least one of R¹ and R², or R³ and R⁴, or R⁵ and R⁶, or R⁷ and R⁸, or a combination thereof, together form a structure represented by the formula:

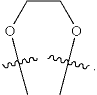

19. A method for producing a polymeric light-emitting device, the method comprising:
providing at least one electrode with at least one monomer in contact therewith; and
at least partially polymerizing the at least one monomer to provide a polymeric layer;
wherein the at least one monomer and the polymeric layer produced therefrom independently comprise at least one lanthanide element, at least one platinum group metal, or a combination thereof; and
wherein the polymeric layer is at least partially electrically conductive;
thereby producing the polymeric light-emitting device.

20. The method of claim 19, wherein polymerizing comprises electropolymerization.

21. The method of claim 19, wherein polymerizing comprises a step-wise polymerization comprising providing a first polymeric layer, followed by providing at least a second polymeric layer.

22. The method of claim 19, wherein the at least one electrode is an anode.

23. The method of claim 19, further comprising providing a cathode on at least a portion of the polymeric layer, such that the anode and the cathode have at least a portion of the polymeric layer positioned therebetween.
